(19) United States
(12) Patent Application Publication
(10) Pub. No.: US 2013/0270616 A1
(43) Pub. Date: Oct. 17, 2013

(54) SEMICONDUCTOR DEVICE

(71) Applicant: SEMICONDUCTOR ENERGY LABORATORY CO., LTD., Atsugi-shi (JP)

(72) Inventor: Shunpei Yamazaki, Tokyo (JP)

(73) Assignee: Semiconductor Energy Laboratory Co., Ltd., Atsugi-shi (JP)

(21) Appl. No.: 13/859,086

(22) Filed: Apr. 9, 2013

(30) Foreign Application Priority Data
Apr. 13, 2012 (JP) 2012-091530

(51) Int. Cl. H01L 29/78

(52) U.S. Cl. CPC H01L 29/78
USPC 257/288

(57) ABSTRACT

A semiconductor device preventing a defect in manufacturing process, such as disconnection of a film to be formed. Further, a semiconductor device with favorable electric characteristics and high performance can be provided. In a top-gate semiconductor device in which a source electrode and a drain electrode are provided in contact with an oxide semiconductor film, a sidewall insulating film is provided to fill a recessed portion between the source electrode and a gate electrode and a recessed portion between the drain electrode and the gate electrode, which cause disconnection of a film to be formed on and in contact with the gate electrode. Further, the sidewall insulating film is provided so that a recessed portion is not formed between the sidewall insulating film and another film included in the semiconductor device.

### BACKGROUND OF THE INVENTION

1. Field of the Invention

The invention disclosed relates to a semiconductor device.

Note that a semiconductor device in this specification refers to general devices which can function by utilizing semiconductor characteristics; for example, a semiconductor element such as a transistor, a semiconductor circuit including a semiconductor element, an electro-optical device such as a display device, and an electronic device are all semiconductor devices.

2. Description of the Related Art

Transistors used for most flat panel displays typified by a liquid crystal display device and a light-emitting display device are formed using silicon semiconductors such as amorphous silicon, single crystal silicon, and polycrystalline silicon provided over glass substrates. Further, transistors formed using such silicon semiconductors are used in integrated circuits (ICs) and the like.

In recent years, attention has been drawn to a technique in which, instead of a silicon semiconductor, a metal oxide exhibiting semiconductor characteristics is used for transistors. Note that in this specification, a metal oxide exhibiting semiconductor characteristics is referred to as an oxide semiconductor.

For example, a technique of using an oxide semiconductor containing at least one element selected from indium (In), gallium (Ga), and zinc (Zn) for a transistor is disclosed (see Patent Document 1 and Patent Document 2).

Further, in a transistor including an oxide semiconductor, hydrogen forms a shallow impurity level in the oxide semiconductor and degrades the electrical characteristics; therefore, to protect the oxide semiconductor against hydrogen, a technique of using an aluminum oxide film as a protective film is disclosed (see Patent Document 3).

The circuit scale (integration degree) of a semiconductor circuit including a transistor and the like is increased with each passing year. For example, central processing units (CPUs), digital signal processors (DSPs) and the like are composed of tens of millions of elements. In such semiconductor integrated circuits, a large number of elements are integrated not only two-dimensionally but also three-dimensionally.

### REFERENCE

### Patent Document

[Patent Document 1] Japanese Published Patent Application No. 2006-165528
[Patent Document 2] Japanese Published Patent Application No. 2007-123861
[Patent Document 3] Japanese Published Patent Application No. 2010-114413

### SUMMARY OF THE INVENTION

In the case where elements such as transistors are integrated three-dimensionally, to improve a yield of a semiconductor circuit to be manufactured, elements to be stacked preferably have a shape with good step coverage. Therefore, in a process for manufacturing the transistor, it is important to suppress disconnection due to the step coverage with a film included in the transistor.

In the case where an element is stacked over a top-gate transistor, a sufficient allowable range for process conditions in forming the element can be ensured by increasing the aspect ratio (ratio of a length in the height direction to a length in the channel length direction) of a gate electrode of the transistor. By increasing the aspect ratio of the gate electrode of the transistor, for example, an allowable range of treatment conditions of a step of exposing a top surface of the gate electrode which is performed to electrically connect the gate electrode and the element can be increased.

However, when the aspect ratio of the gate electrode of the transistor is high, there is a possibility that disconnection occurs in a film which is formed over the gate electrode by a sputtering method or the like which provides low step coverage.

Thus, an object of one embodiment of the present invention is to provide a semiconductor device in which a defect such as disconnection as described above is prevented from occurring in the manufacturing process.

In a variety of semiconductor devices such as semiconductor circuits and display devices, an improvement in the electric characteristics of a transistor included in the semiconductor device results in improvement in the performance of the semiconductor device.

For example, in a transistor including an oxide semiconductor, hydrogen (including water, a hydrogen ion, a hydroxide ion, and the like) and oxygen vacancies in the oxide semiconductor film causes the transistor to have poor electrical characteristics.

For example, the threshold voltage of a transistor which includes an oxide semiconductor including hydrogen and oxygen vacancies tends to shift in the negative direction, and thus the transistor tends to be normally on. This is because charge is generated owing to the hydrogen and oxygen vacancies in the oxide semiconductor film to reduce the resistance of the oxide semiconductor film. It is difficult to reduce the oxygen vacancies in the oxide semiconductor film. For example, oxygen vacancies are easily formed in an oxide semiconductor film in the step of forming or etching the oxide semiconductor film.

Thus, an object of one embodiment of the present invention is to provide a semiconductor device with favorable electric characteristics and high performance and a method for manufacturing the semiconductor device.

In view of the above problems, in a top-gate semiconductor device in which a source electrode and a drain electrode are provided in contact with an oxide semiconductor film, a sidewall insulating film is provided to fill a recessed portion between the source electrode and a gate electrode and a recessed portion between the drain electrode and the gate electrode, the recess portion facilitating disconnection of a film to be formed on and in contact with the gate electrode, whereby the step coverage with the film to be formed over the gate electrode, the source electrode, and the drain electrode can be improved.

To further improve the step coverage with the film to be formed over the gate electrode, the source electrode, and the drain electrode, the sidewall insulating film is preferably provided so that a recessed portion is not formed between the sidewall insulating film and another film included in the semiconductor device.

Thus, one embodiment of the present invention is a semiconductor device including an oxide semiconductor film, a source electrode and a drain electrode provided in contact with the oxide semiconductor film, a gate insulating film provided in contact with the oxide semiconductor film, a gate electrode provided in contact with the gate insulating film between the source electrode and the drain electrode, and a sidewall insulating film provided in contact with a side surface of the gate electrode. The sidewall insulating film fills a recessed portion between the source electrode and the gate electrode and a recessed portion between the drain electrode and the gate electrode and covers part of the source electrode and part of the drain electrode.

Further, it is preferable that part of the periphery of the sidewall insulating film not only cover part of the source electrode and part of the drain electrode but also be positioned at a corner portion which is formed by a surface of the source electrode facing the gate electrode and a top surface of the source electrode and a corner portion which is formed by a surface of the drain electrode facing the gate electrode and a top surface of the drain electrode. Alternatively, the part of the periphery of the sidewall insulating film may be provided to be positioned at corner portions of the gate insulating film covering the corner portions.

When an insulating film which is capable of preventing entry of hydrogen from the outside into an oxide semiconductor film is provided in a transistor including an oxide semiconductor, degradation of the electrical characteristics of the semiconductor device can be prevented. It is preferable that the insulating film have a function of preventing oxygen contained in a film included in the semiconductor device, such as the oxide semiconductor film or a gate insulating film, from being released to the outside. With the function, degradation of the electrical characteristics of the semiconductor device can be further prevented. Examples of the insulating film include a metal oxide film which has an insulating property and is formed by a sputtering method, and the like.

As described above, when the sidewall insulating film is provided to improve the step coverage with the film to be formed over the gate electrode, the source electrode, and the drain electrode, an insulating film can be formed to have high step coverage even by a formation method providing low step coverage, such as a sputtering method, so that a defect such as a disconnection of the film to be formed over the gate insulating film, the sidewall insulating film, and the gate electrode can be prevented.

Further, in one embodiment of the present invention, to increase the on-state current of the semiconductor device, a low-resistance region containing a dopant is preferably provided in the oxide semiconductor film. At this time, second regions that are low-resistance regions between which a first region overlapping with the gate electrode is provided can be provided in the oxide semiconductor film with the use of the gate electrode, the source electrode, and the drain electrode as masks.

Further, with the use of the gate electrode as a mask, low-resistance regions having different dopant concentrations can be provided as the second regions and third regions. Note that the third regions have higher dopant concentration than the second regions.

Furthermore, the low-resistance regions may be provided in the oxide semiconductor film with the use of the gate electrode and the sidewall insulating film as masks.

However, to reduce the off-state current of the semiconductor device, the low-resistance regions including a dopant are not necessarily provided in the oxide semiconductor film.

According to one embodiment of the present invention, in a top-gate semiconductor device in which a source electrode and a drain electrode are provided in contact with an oxide semiconductor film, a sidewall insulating film is provided to fill a recessed portion between the source electrode and a gate electrode and a recessed portion between the drain electrode and the gate electrode and to cover part of the source electrode and part of the drain electrode, whereby the step coverage with a film to be formed over the gate electrode, the source electrode, and the drain electrode can be improved. Therefore, an insulating film which is capable of preventing degradation of the electrical characteristics can be provided without a defect such as a disconnection, so that a semiconductor device with favorable electrical characteristics and high performance can be provided.

According to one embodiment of the present invention, a defect in the manufacturing process, such as a disconnection, can be prevented, so that a semiconductor device can be provided with a high yield and high productivity.

Further, according to one embodiment of the present invention, on-state current can be increased by providing a low-resistance region containing a dopant in an oxide semiconductor film, so that a semiconductor device with favorable electrical characteristics and high performance can be provided.

### BRIEF DESCRIPTION OF THE DRAWINGS

FIGS. 1A and 1B are cross-sectional views each illustrating a transistor.

FIGS. 2A and 2B are cross-sectional views each illustrating a transistor.

FIGS. 3A and 3B are a top view and a cross-sectional view illustrating an example of a transistor.

FIGS. 4A to 4D are cross-sectional views illustrating a method for manufacturing a transistor.

FIGS. 5A to 5C are cross-sectional views illustrating a method for manufacturing a transistor.

FIG. 6 is a cross-sectional view illustrating a method for manufacturing a transistor.

FIGS. 7A and 7B are a top view and a cross-sectional view illustrating an example of a transistor.

FIG. 8 is a cross-sectional view illustrating a method for manufacturing a transistor.

FIGS. 9A and 9B are a top view and a cross-sectional view illustrating an example of a transistor.

FIGS. 10A to 10C are cross-sectional views illustrating a method for manufacturing a transistor.

FIGS. 11A and 11B are a top view and a cross-sectional view illustrating an example of a transistor.

FIGS. 12A and 12B are cross-sectional views illustrating a method for manufacturing a transistor.

FIGS. 13A and 13B are a top view and a cross-sectional view illustrating an example of a transistor.

FIGS. 14A and 14B are cross-sectional views each illustrating an example of a transistor.

FIG. 15 is a cross-sectional view illustrating an example of a transistor.

FIGS. 16A and 16B are a top view and a cross-sectional view illustrating an example of a transistor.

FIGS. 17A and 17B are a cross-sectional view and a circuit diagram illustrating a semiconductor device.

FIG. 18 is a cross-sectional view illustrating a semiconductor device.

FIGS. 19A and 19B are circuit diagrams each illustrating a semiconductor device.

FIGS. 20A and 20B are a circuit diagram of a semiconductor device and a graph showing a relation between time and the potential of a capacitor.

FIGS. 21A and 21B are circuit diagrams each illustrating an example of a semiconductor device.

FIG. 22A is a block diagram illustrating a specific example of a CPU, and

FIGS. 22B and 22C are circuit diagrams each illustrating part of the CPU.

FIGS. 23A to 23F are external views of electronic appliances.

FIGS. 24A to 24C are circuit diagrams illustrating semiconductor devices and a cross-sectional view of part of the semiconductor device.

### DETAILED DESCRIPTION OF THE INVENTION

Hereinafter, embodiments of the present invention will be described in detail with reference to the accompanying drawings. However, the present invention is not limited to the following description and it is easily understood by those skilled in the art that the mode and details can be variously changed without departing from the scope and spirit of the present invention. Therefore, the present invention should not be interpreted as being limited to the description of the embodiments. In addition, in the following embodiments, the same portions or portions having similar functions are denoted by the same reference numerals or the same hatching patterns in different drawings, and description thereof will not be repeated.

Note that in each drawing described in this specification, the size, the film thickness, or the region of each component is exaggerated for clarity in some cases. Therefore, embodiments of the present invention are not limited to such scales.

Note that terms such as “first”, “second”, and “third” in this specification are used in order to avoid confusion among components, and the terms do not limit the components numerically. Therefore, for example, description can be made even when “first” is replaced with “second” or “third”, as appropriate.

Note that, functions of “source” and “drain” may become switched in the case that a direction of a current flow is changed during circuit operation, for example. Therefore, the terms “source” and “drain” can be used to denote the drain and the source, respectively, in this specification.

In this specification, in the case where an etching step is performed after a photolithography step, a mask formed in the photolithography step is removed after the etching step.

### Embodiment 1

In this embodiment, a semiconductor device of one embodiment of the present invention will be described with reference to drawings.

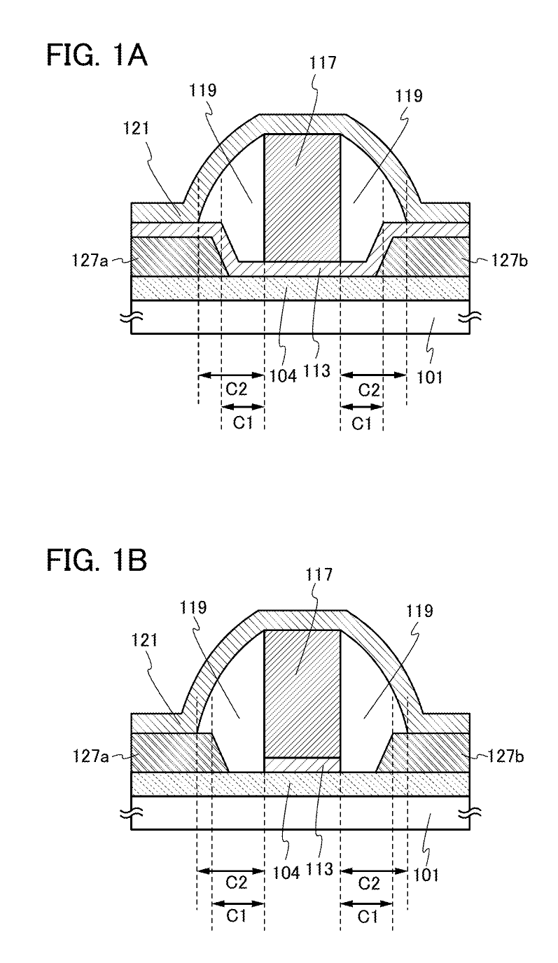

FIGS. 1A and 1B are cross-sectional views each illustrating a transistor which is one embodiment of the present invention.

Each of the transistors illustrated in FIGS. 1A and 1B is a top-gate transistor and includes at least an oxide semiconductor film 104, a gate insulating film 113, a gate electrode 117, a source electrode 127a, a drain electrode 127b, a sidewall insulating film 119, and an insulating film 121, over a substrate 101. Note that a base insulating film may be provided between the substrate 101 and the oxide semiconductor film 104, and an interlayer insulating film may be provided over the insulating film 121.

The transistor illustrated in FIG. 1A has a structure in which the gate insulating film 113 is provided between the sidewall insulating film 119 and each of the source electrode 127a and the drain electrode 127b. The transistor illustrated in FIG. 1B has a structure in which the gate insulating film 113 is not provided between the sidewall insulating film 119 and each of the source electrode 127a and the drain electrode 127b.

Each of the transistors illustrated in FIGS. 1A and 1B is a transistor in which the sidewall insulating film 119 fills a recessed portion between the source electrode 127a and the gate electrode 117 and a recessed portion between the drain electrode 127b and the gate electrode 117, and the sidewall insulating film 119 covers part of the source electrode 127a and part of the drain electrode 127b.

Note that in the transistor illustrated in FIG. 1A, the sidewall insulating film 119 is in contact with a side surface of the gate electrode 117 and a top surface of the gate insulating film 113 as described above. On the other hand, in the transistor illustrated in FIG. 1B, the sidewall insulating film 119 is in contact with the side surface of the gate electrode 117, a top surface of the source electrode 127a, and a top surface of the drain electrode 127b.

In this manner, when the sidewall insulating film 119 is provided so as to fill the recessed portion between the source electrode 127a and the gate electrode 117 and the recessed portion between the drain electrode 127b and the gate electrode 117, even if the aspect ratio of the gate electrode 117 is high and the recessed portions are deep, the step coverage with a film formed over the recessed portions can be favorable.

For example, in the case where the sidewall insulating film 119 is not provided and a film is formed over the gate electrode 117, the source electrode 127a, and the drain electrode 127b by a formation method providing low step coverage, such as a sputtering method, the film to be formed might be disconnected because the recessed portions are deep. The possibility of the disconnection becomes higher as the aspect ratio of the gate electrode 117 is increased (as the recessed portion becomes deeper).

In the case where the insulating film 121, which can suppress degradation of the electrical characteristics of the transistor, is formed by a formation method providing low step coverage, such as a sputtering method, a defect such as disconnection can be prevented in such a manner that the sidewall insulating film 119 is provided to fill the recessed portions in advance to improve the step coverage with a film to be formed over the recessed portions and then the insulating film 121 is formed; accordingly, the transistor having favorable electrical characteristics can be manufactured with a high yield.

At this time, if a recessed portion is formed by the formed sidewall insulating film 119, the source electrode 127a, and the drain electrode 127b, there is still a possibility that disconnection occurs in the film to be formed over the gate electrode 117, the source electrode 127a, and the drain electrode 127b. Therefore, as illustrated in FIGS. 1A and 1B, the sidewall insulating film 119 is preferably formed to cover the part of the source electrode 127a and the part of the drain electrode 127b.

Specifically, the sidewall insulating film 119 is preferably formed so that a distance C2 from the side surface of the gate electrode 117 to a side edge of the sidewall insulating film 119 is longer than a distance C1 from the side surface of the gate electrode 117 to each of corner portions of the gate insulating film 113 which are generated by forming the gate insulating film 113 to cover the source electrode 127a and the drain electrode 127b (see FIG. 1A). Alternatively, the sidewall insulating film 119 is preferably formed so that the distance C2 is longer than a distance C1 from the side surface of the gate electrode 117 to each of a corner portion which is formed by a surface of the source electrode 127a facing the gate electrode 117 and the top surface of the source electrode 127a and a corner portion which is formed by a surface of the drain electrode 127b facing the gate electrode 117 and the top surface of the drain electrode 127b (see FIG. 1B).

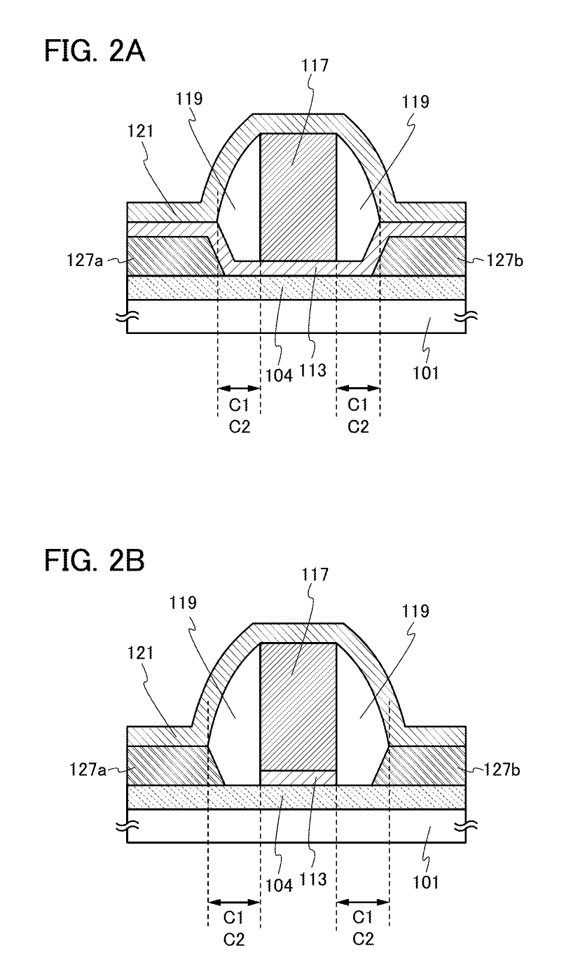

In one embodiment of the present invention, the sidewall insulating film 119 is preferably provided, so that the formed sidewall insulating film 119 and the source and drain electrodes 127a and 127b do not form a recessed portion; therefore, the sidewall insulating film 119 may be provided so that the distance C1 corresponds to the distance C2 (see FIGS. 2A and 2B). The transistors illustrated in FIGS. 2A and 2B have the same structure (e.g., the kinds of the films) as those illustrated in FIGS. 1A and 1B except for the relation between the distance C1 and the distance C2.

In other words, the transistor of one embodiment of the present invention may have a structure in which the side edges of the sidewall insulating film 119 are positioned at the corner portions of the gate insulating film 113 which are generated by forming the gate insulating film 113 to cover the source electrode 127a and the drain electrode 127b (see FIG. 2A). Alternatively, the transistor of one embodiment of the present invention may have a structure in which the side edges of the sidewall insulating film 119 are positioned at the corner portion formed by the surface of the source electrode 127a facing the gate electrode 117 and the top surface of the source electrode 127a and at the corner portion formed by the surface of the drain electrode 127b facing the gate electrode 117 and the top surface of the drain electrode 127b (see FIG. 2B).

Note that the corner portions indicate regions where the side edges of the sidewall insulating film 119 are formed. Accordingly, although the source electrode 127a and the drain electrode 127b are illustrated such that the top surface and the side surface are in contact with each other to form an angle in the drawing, the shape thereof is changed in response to process conditions of the transistor; therefore, the corner portions may have any shape such as a linear shape or a curved shape.

As described above, according to one embodiment of the present invention, a defect such as disconnection of a film formed over the gate electrode, the source electrode, and the drain electrode, which occurs due to an increase in the aspect ratio of the gate electrode, can be prevented from occurring at the recessed portions formed by the gate electrode, the source electrode, and the drain electrode; thus the transistor can be manufactured with a high yield and high productivity.

For example, an insulating film which can suppress degradation of the electrical characteristics of the transistor can be provided without a defect such as disconnection; thus, the transistor of one embodiment of the present invention has favorable electrical characteristics and exhibits high performance.

In the case where another element (a transistor or a capacitor) is stacked over the transistor that is one embodiment of the present invention, since the aspect ratio of the gate electrode can be increased, a sufficient allowable range of process conditions at the time of formation of the element can be ensured. Accordingly, the element can be formed over the transistor with a high yield.

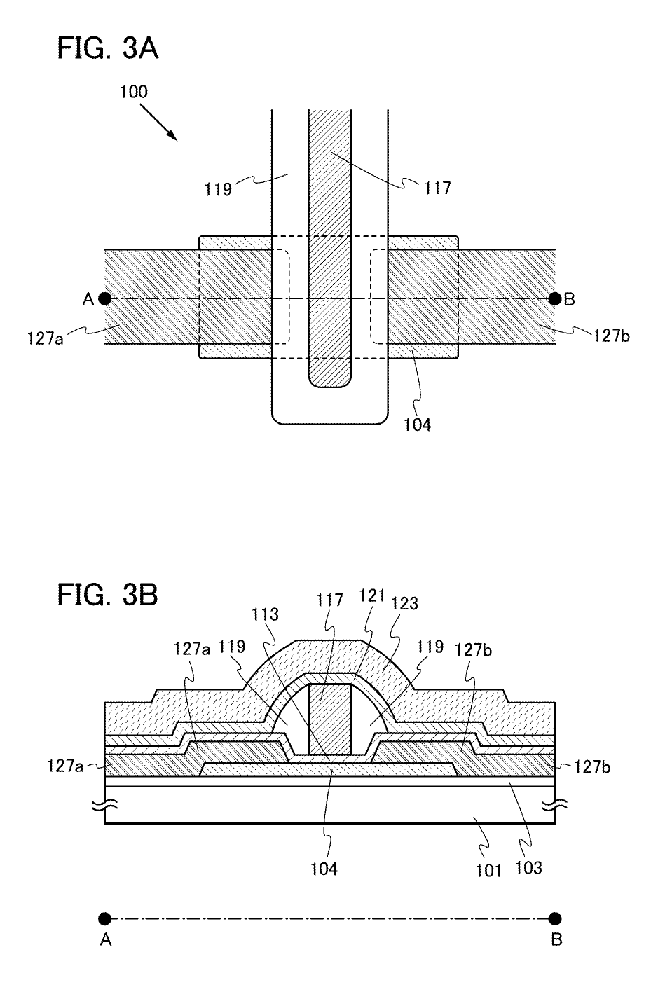

Next, details of the structure of the transistor that is one embodiment of the present invention are described. Here, description is made using a transistor 100 illustrated in FIGS. 3A and 3B as an example. FIG. 3A is a top view of the transistor 100 and FIG. 3B is a cross-sectional view of the transistor 100 along line A-B in FIG. 3A.

The transistor 100 has the structure of the transistor in FIG. 1A which further includes a base insulating film and an interlayer insulating film.

That is, the transistor 100 includes, over the substrate 101, a base insulating film 103, the oxide semiconductor film 104, the gate insulating film 113, the gate electrode 117, the source electrode 127a, the drain electrode 127b, the sidewall insulating film 119, the insulating film 121, and an interlayer insulating film 123 (see also FIGS. 1A and 1B).

In the transistor 100, the base insulating film 103 is provided in contact with the substrate 101. The oxide semiconductor film 104 is provided in contact with the base insulating film 103. The source electrode 127a and the drain electrode 127b are provided in contact with the oxide semiconductor film 104. The gate insulating film 113 is provided in contact with the oxide semiconductor film 104, the source electrode 127a, and the drain electrode 127b. The gate electrode 117 is provided in contact with the gate insulating film 113 between the source electrode 127a and the drain electrode 127b.

Further, the sidewall insulating film 119 is provided in contact with the side surface of the gate electrode 117 and the top surface of the gate insulating film 113. Specifically, the gate insulating film 113 is provided between the sidewall insulating film 119 and each of the source electrode 127a and the drain electrode 127b, and the sidewall insulating film 119 is provided to fill the recessed portion between the source electrode 127a and the gate electrode 117 and the recessed portion between the drain electrode 127b and the gate electrode 117 and to cover part of the source electrode 127a and part of the drain electrode 127b.

The insulating film 121 is provided in contact with the gate insulating film 113, the sidewall insulating film 119, and the gate electrode 117. The interlayer insulating film 123 is provided in contact with the insulating film 121.

As described above, in the transistor 100, the recessed portion formed between the source electrode 127a and the gate electrode 117 and the recessed portion formed between the drain electrode 127b and the gate electrode 117 are filled with the sidewall insulating film 119. Therefore, the step coverage with a film to be formed over the recessed portions is improved and thus a defect such as disconnection is prevented at the recessed portion, so that a transistor having favorable electrical characteristics can be manufactured.

Note that the transistor 100 can have not only a structure in which the line width of each of the source electrode 127a and the drain electrode 127b in the channel width direction is smaller than the line width of the oxide semiconductor film 104 in the channel width direction (see FIG. 3A), but also a structure in which the line width of each of the source electrode 127a and the drain electrode 127b in the channel width direction is larger than the line width of the oxide semiconductor film 104 in the channel width direction.

The gate electrode 117 also functions as a gate wiring. The source electrode 127a also functions as a source wiring. The drain electrode 127b also functions as a drain wiring. Note that openings may be provided in one or more of the gate insulating film 113, the insulating film 121, and the interlayer insulating film 123; and a gate wiring, a source wiring, and a drain wiring may be provided to be in contact with the gate electrode 117, the source electrode 127a, and the drain electrode 127b, respectively.

There is no particular limitation on the property of a material and the like of the substrate 101 as long as the material has heat resistance enough to withstand at least heat treatment to be performed later. For example, a glass substrate, a ceramic substrate, a quartz substrate, a sapphire substrate, or the like may be used as the substrate 101. Alternatively, a single crystal semiconductor substrate or a polycrystalline semiconductor substrate made of silicon, silicon carbide, or the like, a compound semiconductor substrate made of silicon germanium or the like, an SOI substrate, or the like may be used as the substrate 101. Furthermore, any of these substrates further provided with a semiconductor element may be used as the substrate 101.

Note that the base insulating film 103 is not necessarily provided, and the oxide semiconductor film 104 may be formed directly on the substrate 101. In the case where a flexible substrate is used as the substrate 101, the oxide semiconductor film 104 may be formed over the base insulating film 103 over the flexible substrate or may be formed directly on the flexible substrate.

Alternatively, a separation layer may be provided between the substrate 101 and the transistor 100. The separation layer can be used when part or the whole of a semiconductor device formed over the separation layer is separated from the substrate 101 and transferred onto another substrate. In such a case, the semiconductor device can be transferred to a substrate having low heat resistance or a flexible substrate as well.

The base insulating film 103 is an insulating film which prevents diffusion of an impurity element such as hydrogen (including moisture or hydroxyl group) from the substrate 101 into the oxide semiconductor film 104. The base insulating film 103 preferably has an effect of supplying part of its oxygen to the oxide semiconductor film 104 by being heated in a manufacturing process of the transistor 100 to fill the oxygen vacancies in the oxide semiconductor film 104. Accordingly, the base insulating film 103 is preferably an insulating film containing oxygen.

For example, the base insulating film 103 can be formed using an insulating film selected from the following films or a stacked layer of plural insulating films selected from the following films: oxide insulating films such as a silicon oxide film, a gallium oxide film, an aluminum oxide film, a zinc oxide film, and a Ga—Zn-based metal oxide film; oxynitride insulating films such as a silicon oxynitride film, a gallium oxynitride film, an aluminum oxynitride film, an yttrium oxynitride film, and a hafnium oxynitride film; and nitride oxide insulating films such as a silicon nitride oxide film. Note as for a material applicable to the base insulating film 103, “nitride oxide” means that the material contains more nitrogen than oxygen, and “oxynitride” means that to the material that contains more oxygen than nitrogen.

The base insulating film 103 can be formed using any of the materials given above by a chemical vapor deposition (CVD) method, a sputtering method, a molecular beam epitaxy (MBE) method, or a pulsed laser deposition (PLD) method.

In order for the base insulating film 103 to supply part of its oxygen to the oxide semiconductor film 104 by being heated in the manufacturing process of the transistor 100, the base insulating film 103 is preferably an insulating film which releases part of its oxygen by being heated. Specifically, the base insulating film 103 is preferably an insulating film of which the amount of released oxygen converted into oxygen atoms is greater than or equal to 1.0×10¹⁸ cm⁻³, preferably greater than or equal to 3.0×10²⁰ cm⁻³, in thermal desorption spectroscopy (TDS) analysis.

A method for quantifying the amount of released oxygen which is converted into oxygen atoms, with the use of TDS analysis is described below.

The amount of released gas in TDS analysis is proportional to the integral value of a spectrum. Therefore, the amount of released gas can be calculated from the ratio between the integral value of a spectrum of an insulating film and the reference value of a standard sample. The reference value of a standard sample refers to the ratio of the density of a predetermined atom contained in a sample to the integral value of a spectrum.

For example, the number of released oxygen molecules (N_{O2}) from an insulating film can be found according to the formula described below with the TDS analysis results of a silicon wafer containing hydrogen at a predetermined density which is the standard sample and the TDS analysis results of the insulating film. Here, all spectra having a mass number of 32 which are obtained by the TDS analysis are assumed to originate from an oxygen molecule. CH₃OH, which is given as a gas having a mass number of 32, is not taken into consideration on the assumption that it is unlikely to be present. Further, an oxygen molecule including an oxygen atom having a mass number of 17 or 18 which is an isotope of an oxygen atom is not taken into consideration either because the proportion of such a molecule in the natural world is minimal

$${N}_{O 2} = \frac{{N}_{H 2}}{{S}_{H 2}} \times {S}_{O 2} \times α \qquad [ Formula 1 ]$$

N_{H2} is the value obtained by conversion of the number of hydrogen molecules desorbed from the standard sample into densities. S_{H2} is the integral value of a spectrum when the standard sample is subjected to TDS analysis. Here, the reference value of the standard sample is set to N_{H2}/S_{H2}. S_{O2} is the integral value of a spectrum when the insulating film is subjected to TDS analysis. α is a coefficient affecting the intensity of the spectrum in the TDS analysis. Japanese Published Patent Application No. H6-275697 can be referred to for details of the above formula. Note that the above value of the amount of released oxygen is obtained by measurement with a thermal desorption spectrometer produced by ESCO Ltd., EMD-WA1000S/W using a silicon wafer containing hydrogen atoms at 1×10¹⁶ cm⁻² as the standard sample.

Further, in the TDS analysis, oxygen is partly detected as an oxygen atom. The ratio between oxygen molecules and oxygen atoms can be calculated from the ionization rate of the oxygen molecules. Note that, since the above α includes the ionization rate of the oxygen molecules, the number of the released oxygen atoms can also be estimated through the evaluation of the number of the released oxygen molecules.

Note that N_{O2} is the number of the released oxygen molecules. For the insulating film, the amount of released oxygen when converted into oxygen atoms is twice the number of the released oxygen molecules.

An example of the insulating film which releases part of its oxygen by being heated is an insulating film containing oxygen in a proportion higher than that in the stoichiometric composition, such as a silicon oxynitride film containing excess oxygen or a silicon oxide (SiOₓ(x>2)) film containing excess oxygen. The silicon oxide (SiOₓ (x>2)) film containing excessive oxygen is the one whose number of oxygen atoms per unit volume is more than twice the number of silicon atoms per unit volume. The number of silicon atoms and the number of oxygen atoms per unit volume are measured by Rutherford backscattering spectrometry.

In the manufacturing process of the transistor 100, hydrogen that is contained in the base insulating film 103 is diffused into the oxide semiconductor film 104 to reduce the resistance of the oxide semiconductor film 104, which might cause the transistor 100 to have poor electric characteristics. Therefore, hydrogen in the base insulating film 103 is preferably reduced.

The base insulating film 103 can be formed to a thickness greater than or equal to 5 nm and less than or equal to 3000 nm.

Note that for the transistor 100, alkali metal such as Li or Na is an impurity, and the alkali metal might lead to poor electrical characteristics when the impurity is diffused into the oxide semiconductor film 104. Therefore, a nitride insulating film may be provided between the substrate 101 and the base insulating film 103. The nitride insulating film can be formed using silicon nitride, aluminum nitride, or the like by a method which is similar to that of the base insulating film 103.

The oxide semiconductor film 104 at least includes a channel formation region. The oxide semiconductor film 104 preferably contains at least indium (In) or zinc (Zn). Alternatively, both In and Zn are preferably contained. In order to reduce variation in electrical characteristics of the transistor including the oxide semiconductor, the oxide semiconductor film preferably contains one or more of stabilizers in addition to In and/or Zn.

As a stabilizer, gallium (Ga), tin (Sn), hafnium (Hf), aluminum (Al), zirconium (Zr), and the like can be given.

As another stabilizer, lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) can be given.

As the oxide semiconductor, for example, indium oxide, tin oxide, zinc oxide, an In—Zn-based oxide, a Sn—Zn-based oxide, an Al—Zn-based oxide, a Zn—Mg-based oxide, a Sn—Mg-based oxide, an In—Mg-based oxide, an In—Ga-based oxide, an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide can be used.

Note that here, for example, an “In—Ga—Zn-based oxide” means an oxide containing In, Ga, and Zn as its main components and there is no particular limitation on the ratio of In, Ga, and Zn. The In—Ga—Zn-based oxide may contain a metal element other than the In, Ga, and Zn.

Alternatively, a material represented by InMO₃(ZnO)ₘ (m>0 is satisfied, and m is not an integer) may be used as an oxide semiconductor. Note that M represents one or more metal elements selected from Ga, Fe, Mn, and Co. Alternatively, as the oxide semiconductor, a material expressed by a chemical formula, In₂SnO₅(ZnO)ₙ (n>0, n is a natural number) may be used.

For example, an In—Ga—Zn-based oxide with an atomic ratio of In:Ga:Zn=1:1:1 (=⅓:⅓:⅓), In:Ga:Zn=2:2:1 (=⅖:⅖:⅕), In:Ga:Zn=3:1:2 (=½:⅙:⅓), or any of oxides whose composition is in the neighborhood of the above compositions can be used. Alternatively, an In—Sn—Zn-based oxide with an atomic ratio of In:Sn:Zn=1:1:1 (=⅓:⅓:⅓), In:Sn:Zn=2:1:3 (=⅓:⅙:½), or In:Sn:Zn=2:1:5 (=¼:⅛:⅝), or an oxide with an atomic ratio close to the above atomic ratios may be used.

However, without limitation to the materials given above, a material with an appropriate composition may be used in accordance with needed semiconductor characteristics and electric characteristics (e.g., field-effect mobility, the threshold voltage, and variation). In order to obtain necessary semiconductor characteristics, it is preferable that the carrier density, the impurity concentration, the defect density, the atomic ratio of a metal element to oxygen, the interatomic distance, the density, and the like be set to be appropriate.

For example, with an In—Sn—Zn-based oxide, high mobility can be realized relatively easily. However, mobility can be increased by reducing the defect density in a bulk also in the case of using an In—Ga—Zn-based oxide.

Further, the energy gap of the oxide semiconductor applicable to the oxide semiconductor film 104 is 2 eV or more, preferably 2.5 eV or more, more preferably 3 eV or more. In this manner, the off-state current of a transistor can be reduced by using an oxide semiconductor having a wide energy gap.

Note that the oxide semiconductor film 104 may have an amorphous structure, a single crystal structure, or a polycrystalline structure.

The oxide semiconductor film 104 may be in a non-single-crystal state, for example. The non-single-crystal state is, for example, structured by at least one of c-axis aligned crystal (CAAC), polycrystal, microcrystal, and an amorphous part. The density of defect states of an amorphous part is higher than those of microcrystal and CAAC. The density of defect states of microcrystal is higher than that of CAAC. Note that an oxide semiconductor including CAAC is referred to as a CAAC-OS (c-axis aligned crystalline oxide semiconductor).

For example, the oxide semiconductor film 104 may include a CAAC-OS. In the CAAC-OS, for example, c-axes are aligned, and a-axes and/or b-axes are not macroscopically aligned.

For example, the oxide semiconductor film 104 may include microcrystal. Note that an oxide semiconductor including microcrystal is referred to as a microcrystalline oxide semiconductor. A microcrystalline oxide semiconductor film includes microcrystal (also referred to as nanocrystal) with a size greater than or equal to 1 nm and less than 10 nm, for example. Alternatively, a microcrystalline oxide semiconductor film, for example, includes a crystal-amorphous mixed phase structure where crystal parts (each of which is greater than or equal to 1 nm and less than 10 nm) are distributed.

For example, the oxide semiconductor film 104 may include an amorphous part. Note that an oxide semiconductor including an amorphous part is referred to as an amorphous oxide semiconductor. An amorphous oxide semiconductor film, for example, has disordered atomic arrangement and no crystalline component. Alternatively, an amorphous oxide semiconductor film is, for example, absolutely amorphous and has no crystal part.

The oxide semiconductor film 104 may be a mixed film including any of a CAAC-OS, a microcrystalline oxide semiconductor, and an amorphous oxide semiconductor. The mixed film, for example, includes a region of an amorphous oxide semiconductor, a region of a microcrystalline oxide semiconductor, and a region of a CAAC-OS. Further, the mixed film may have a stacked structure including a region of an amorphous oxide semiconductor, a region of a microcrystalline oxide semiconductor, and a region of a CAAC-OS, for example.

Note that the oxide semiconductor film 104 may be in a single-crystal state, for example.

An oxide semiconductor film 104 preferably includes a plurality of crystal parts. In each of the crystal parts, the c-axis is preferably aligned in a direction parallel to a normal vector of a surface where the oxide semiconductor film is formed or a normal vector of a surface of the oxide semiconductor film. Note that, among crystal parts, the directions of the a-axis and the b-axis of one crystal part may be different from those of another crystal part. An example of such an oxide semiconductor film is a CAAC-OS film.

As the oxide semiconductor film 104, a CAAC-OS (c-axis aligned crystalline oxide semiconductor) film that is one of oxide semiconductor films having crystallinity is preferably used.

The CAAC-OS film is not absolutely amorphous. The CAAC-OS film, for example, includes an oxide semiconductor with a crystal-amorphous mixed phase structure where crystal parts and amorphous parts are intermingled. Note that in most cases, the crystal part fits inside a cube whose one side is less than 100 nm. From the observation with a transmission electron microscope (TEM), a boundary between the amorphous part and the crystal part and a boundary between the crystal parts in the CAAC-OS film are not clearly detected. Further, with the TEM, a grain boundary in the CAAC-OS film is not found. Thus, in the CAAC-OS film, a reduction in electron mobility, due to the grain boundary, is suppressed.

In each of the crystal parts included in the CAAC-OS film, for example, the c-axis is aligned in a direction parallel to a normal vector of a surface where the CAAC-OS film is formed or a normal vector of a surface of the CAAC-OS film. Further, in each of the crystal parts, metal elements are arranged in a triangular or hexagonal configuration when seen from the direction perpendicular to the a-b plane, and metal atoms are arranged in a layered manner or metal atoms and oxygen atoms are arranged in a layered manner when seen from the direction perpendicular to the c-axis. Note that, among crystal parts, the directions of an a-axis and a b-axis of one crystal part may be different from those of another crystal part. In this specification, a term “perpendicular” includes a range from 80° to 100°, preferably from 85° to 95°. In addition, a term “parallel” includes a range from −10° to 10°, preferably from −5° to 5°.

In the CAAC-OS film, distribution of crystal parts is not necessarily uniform. For example, in the formation process of the CAAC-OS film, in the case where crystal growth occurs from a surface side of the oxide semiconductor film, the proportion of crystal parts in the vicinity of the surface of the oxide semiconductor film is higher than that in the vicinity of the surface where the oxide semiconductor film is formed in some cases. Further, when an impurity is added to the CAAC-OS film, the crystal part in a region to which the impurity is added becomes amorphous in some cases.

Since the c-axes of the crystal parts included in the CAAC-OS film are aligned in the direction parallel to a normal vector of a surface where the CAAC-OS film is formed or a normal vector of a surface of the CAAC-OS film, the directions of the c-axes may be different from each other depending on the shape of the CAAC-OS film (the cross-sectional shape of the surface where the CAAC-OS film is formed or the cross-sectional shape of the surface of the CAAC-OS film). Hence, the c-axes of the crystal parts are aligned in the direction parallel to a normal vector of the surface where the CAAC-OS film is formed or a normal vector of the surface of the CAAC-OS film. The crystal part is formed by film formation or by performing treatment for crystallization such as heat treatment after film formation.

With the use of the CAAC-OS film in a transistor, change in electric characteristics of the transistor due to irradiation with visible light or ultraviolet light is small. Thus, the transistor has high reliability.

Nitrogen may be substituted for part of constituent oxygen of the oxide semiconductor film 104.

In a transistor including an oxide semiconductor, hydrogen (including water, a hydrogen ion, a hydroxide ion, and the like) and oxygen vacancies in the oxide semiconductor film generate electric charge, thus increasing the carrier density of the oxide semiconductor film and reducing the resistance of the oxide semiconductor film. Accordingly, the threshold voltage of a transistor that includes an oxide semiconductor film including hydrogen and oxygen vacancies tends to shift in the negative direction, and thus the transistor tends to be normally on.

Thus, it is preferable that impurities such as hydrogen be sufficiently removed from the oxide semiconductor film 104 so that the oxide semiconductor film 104 is highly purified. Specifically, the oxide semiconductor film 104 preferably has a hydrogen concentration of 5×10¹⁹ atoms/cm³ or lower, preferably 5×10¹⁸ atoms/cm³ or lower, further preferably 5×10¹⁷ atoms/cm³ or lower. The hydrogen concentration is measured by secondary ion mass spectrometry (SIMS). Further, the oxide semiconductor film 104 is preferably in a supersaturated state in which the oxygen content is in excess of that of that in the stoichiometric composition.

It is preferable that the oxide semiconductor film 104 be highly purified to contain few impurities such as copper, aluminum, and chlorine. In the manufacturing process of the transistor 100 described later, steps in which these impurities are not mixed or attached to a surface of the oxide semiconductor film 104 are preferably selected as appropriate. In the case where the impurities are attached to the surface of the oxide semiconductor film 104, the impurities on the surface of the oxide semiconductor film 104 are preferably removed by exposure to oxalic acid or dilute hydrofluoric acid or plasma treatment (such as N₂O plasma treatment). Specifically, the copper concentration of the oxide semiconductor film 104 is 1×10¹⁸ atoms/cm³ or lower, preferably 1×10¹⁷ atoms/cm³ or lower. Furthermore, the aluminum concentration of the oxide semiconductor film 104 is 1×10¹⁸ atoms/cm³ or lower. Moreover, the chlorine concentration of the oxide semiconductor film 104 is 2×10¹⁸ atoms/cm³ or lower. Consequently, the transistor 100 can have favorable electric characteristics.

In the case where an oxide semiconductor film such as a single crystal oxide semiconductor film or a polycrystalline oxide semiconductor film, or a CAAC-OS film is used as the oxide semiconductor film 104, by improving the surface planarity of the oxide semiconductor film 104, the transistor can have higher field-effect mobility than a transistor including an amorphous oxide semiconductor film. In order to improve the surface planarity of the oxide semiconductor film 104, the oxide semiconductor film 104 is preferably formed over a planar surface. Specifically, the oxide semiconductor may be formed over a surface with the average surface roughness (Rₐ) of less than or equal to 0.15 nm, preferably less than or equal to 0.1 nm.

Note that Rₐ is obtained by expanding arithmetic mean deviation, which is defined by JIS B 0601, into three dimensions so as to be applicable to a surface. Moreover, Rₐ can be expressed as average value of the absolute values of deviations from a reference surface to a specific surface and is defined by the following formula.

$$Ra = \frac{1}{{S}_{0}} {\int }_{y 1}^{y 2} {\int }_{x 1}^{x 2} \vert f ( x , y ) - {Z}_{0} \vert d x d y \qquad [ Formula 2 ]$$

Here, the specific surface is a surface which is a target of roughness measurement, and is a quadrilateral region which is specified by four points represented by the coordinates (x₁, y₁, f(x₁, y₁)), (x₁, y₂, f(x₁, y₂)), (x₂, y₁, f(x₂, y₁)), and (x₂, y₂, f(x₂, y₂)). So represents the area of a rectangle which is obtained by projecting the specific surface on the xy plane, and Z₀ represents the height of the reference surface (the average height of the specific surface). Note that Rₐ can be measured using an atomic force microscope (AFM).

However, an oxide semiconductor is not limited to the above; an oxide semiconductor with an appropriate composition may be used for the oxide semiconductor film 104 depending on needed electrical characteristics (e.g., field-effect mobility, threshold voltage, and variation). In order to obtain the required transistor characteristics, it is preferable that the oxide semiconductor film 104 be formed using an oxide semiconductor in which the carrier concentration, the impurity concentration, the defect density, the atomic ratio between a metal element and oxygen, the interatomic distance, the density, and the like are set to appropriate values.

For example, high field-effect mobility can be obtained relatively easily in the case of using an In—Sn—Zn oxide. Note that field-effect mobility can be increased by reducing the defect density in a bulk also in the case of using an In—Ga—Zn-based oxide.

A single-layer structure composed of one kind of oxide semiconductor film or a stacked-layer structure composed of plural kinds of oxide semiconductor films can be used for the oxide semiconductor film 104. For example, a stacked-layer structure including at least two of an amorphous oxide semiconductor film, a polycrystalline oxide semiconductor film, and a CAAC-OS film can be used.

Alternatively, the oxide semiconductor film 104 may have a stacked-layer structure composed of oxide semiconductor films having different compositions. Specifically, a stacked-layer structure including a first oxide semiconductor film (hereinafter referred to as an upper layer) which includes a surface in contact with the gate insulating film 113 and a second oxide semiconductor film (hereinafter referred to as a lower layer) whose top surface is in contact with the first oxide semiconductor film and which has a different composition from the first oxide semiconductor film may be employed. Note that most part of the channel formation region is included in the upper layer. This is because the upper layer is closer to the gate electrode 117 than the lower layer is.

In the case where the upper layer and the lower layer both contain indium, gallium, and zinc, concentrations are preferably set such that the indium concentration of the upper layer is higher than that of the lower layer and the gallium concentration of the lower layer is higher than that of the upper layer, or/and such that the indium concentration of the upper layer is higher than the gallium concentration of the upper layer and the gallium concentration of the lower layer is higher than the indium concentration of the lower layer.

Thus, the field-effect mobility of the transistor 100 can be increased and formation of a parasitic channel can be prevented. Specifically, a high indium concentration of the upper layer can cause an increase in the field-effect mobility of the transistor 100. This is because, in an oxide semiconductor, the s orbital of heavy metal mainly contributes to carrier transfer, and when the In content in the oxide semiconductor is increased, overlaps of the s orbitals are increased. In addition, a high gallium concentration of the lower layer leads to prevention of release of oxygen, which can prevent formation of a parasitic channel in the upper layer. This is because Ga has larger energy needed for forming oxygen vacancies than In, so that oxygen vacancies are less likely to be generated.

As the gate insulating film 113, an insulating film selected from an oxide insulating film, an oxynitride insulating film, and a nitride oxide insulating film that are applicable to the base insulating film 103 or a plurality of insulating films selected from these films can be used.

The gate insulating film 113 can be formed using a film including a hafnium oxide film, a yttrium oxide film, a hafnium silicate (HfSiₓO_{y} (x>0, y>0)) film, a hafnium silicate film to which nitrogen is added, a hafnium aluminate (HfAlₓO_{y} (x>0, y>0)) film, or a lanthanum oxide film (i.e., a film formed of what is called a high-k material). By using such a film, gate leakage current can be reduced.

The gate insulating film 113 preferably has a thickness greater than or equal to 5 nm and less than or equal to 300 nm. In order that the transistor is miniaturized or the on-state current and the field-effect mobility of the transistor be improved, the gate insulating film 113 is preferably formed thin. For example, the thickness of the gate insulating film 113 is preferably greater than or equal to 5 nm and less than or equal to 50 nm, more preferably greater than or equal to 10 nm and less than or equal to 30 nm.

The gate electrode 117 can be formed using a metal element selected from aluminum, titanium, chromium, copper, manganese, yttrium, molybdenum, silver, tantalum, and tungsten; an alloy containing any of these metal elements as a component; an alloy containing any of these metal elements in combination; or the like. Further, the gate electrode 117 may have a single-layer structure or a stacked-layer structure of two or more layers.

The gate electrode 117 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal element.

As the gate electrode 117, an In—Ga—Zn-based oxynitride semiconductor film, an In—Sn-based oxynitride semiconductor film, an In—Ga-based oxynitride semiconductor film, an In—Zn-based oxynitride semiconductor film, a Sn-based oxynitride semiconductor film, an In-based oxynitride semiconductor film, a film of a metal nitride (such as InN or ZnN), or the like is preferably used. Specifically, any of these films whose resistivity is greater than or equal to 1×10⁻⁴ Ω·cm and less than or equal to 1×10⁻¹ Ω·cm, preferably greater than or equal to 1×10⁻⁴ Ω·cm and less than or equal to 1×10⁻² Ω·cm is preferably used. These films each have a work function of 5 eV or higher, preferably 5.5 eV or higher and the electron affinity of each of these films is larger than that of an oxide semiconductor; thus, the threshold voltage of the electrical characteristics of the transistor including an oxide semiconductor can be positive. Accordingly, what is called a normally-off switching element can be obtained. For example, in the case of using an In—Ga—Zn-based oxynitride semiconductor film, an In—Ga—Zn-based oxynitride semiconductor film having a higher nitrogen concentration than at least the oxide semiconductor film 104, specifically, an In—Ga—Zn-based oxynitride semiconductor film having a nitrogen concentration of higher than or equal to 7 at. % is used.

The source electrode 127a and the drain electrode 127b can be formed using a metal element selected from aluminum, titanium, chromium, copper, manganese, yttrium, molybdenum, silver, tantalum, and tungsten; an alloy containing any of these metal elements as a component; an alloy containing any of these metal elements in combination; or the like. The source electrode 127a and the drain electrode 127b may have a single-layer structure or a stacked-layer structure of two or more layers. Note that a transparent conductive material containing indium oxide, tin oxide, or zinc oxide may be used.

As the sidewall insulating film 119, an insulating film selected from an oxide insulating film, an oxynitride insulating film, and a nitride oxide insulating film that are applicable to the base insulating film 103 and a nitride insulating film that can be provided between the substrate 101 and the base insulating film 103, or a plurality of insulating films selected from these films can be used.

The width of the sidewall insulating film 119 can be selected as appropriate as long as the sidewall insulating film 119 can fill the recessed portion between the source electrode 127a and the gate electrode 117 and the recessed portion between the drain electrode 127b and the gate electrode 117 and can cover part of the source electrode 127a and part of the drain electrode 127b.

The insulating film 121 can suppress degradation of the electrical characteristics of the transistor 100. For example, the insulating film 121 is preferably capable of preventing hydrogen (including water, hydrogen ions, hydroxide ions, and the like) from entering the oxide semiconductor film 104 from the outside. Further, the insulating film 121 is preferably capable of preventing oxygen contained in a film included in the semiconductor device, such as the oxide semiconductor film 104 or the gate insulating film 113, from being released to the outside.

Specifically, it is preferable that the insulating film 121 be a dense insulating film. Examples of the dense insulating film include a metal oxide film which is formed by a sputtering method and has an insulating property, in particular, an aluminum oxide film which is formed by a sputtering method. When the aluminum oxide film has high density (the film density is higher than or equal to 3.2/cm³, preferably higher than or equal to 3.6/cm³), the aluminum oxide film can prevent impurities such as moisture in the air from entering the oxide semiconductor film 104. Further, the aluminum oxide film can prevent oxygen contained in a component of the transistor 100 from being released to the outside of the transistor 100.

Thus, the insulating film 121 functions as a barrier film which prevents moisture from entering the oxide semiconductor film 104 and also as a barrier film which prevents oxygen which is a main constituent material of the oxide semiconductor film 104 from being released, in and after the manufacturing process of the transistor 100, which enables the manufactured transistor 100 to have favorable electric characteristics. However, a sputtering method generally provides low step coverage; thus there is a possibility that a defect such as disconnection of the insulating film 121 occurs due to the recessed portion between the source electrode 127a and the gate electrode 117 and the recessed portion between the drain electrode 127b and the gate electrode 117. When the disconnection occurs, the electrical characteristics of the transistor 100 deteriorate. In view of this, the transistor 100 has a structure in which the recessed portions are filled with the sidewall insulating film 119 and thus the insulating film 121 is formed without a defect such as disconnection; therefore, the transistor 100 has favorable electrical characteristics.

Further, specific examples of the insulating film 121 other than the aluminum oxide film include metal oxide films having an insulating property, such as films of aluminum oxynitride, gallium oxide, gallium oxynitride, yttrium oxide, yttrium oxynitride, hafnium oxide, and hafnium oxynitride. Note that the film density can be measured by Rutherford backscattering spectrometry (RBS) or X-ray reflection (XRR).

As the interlayer insulating film 123, an insulating film selected from oxide insulating films, oxynitride insulating films, and nitride oxide insulating films that are applicable to the base insulating film 103 or a stacked layer of a plurality of insulating films selected from these films can be used.

The interlayer insulating film 123 preferably has a thickness greater than or equal to 5 nm and less than or equal to 3000 nm.

Next, a method for manufacturing the transistor 100 is described with reference to drawings.

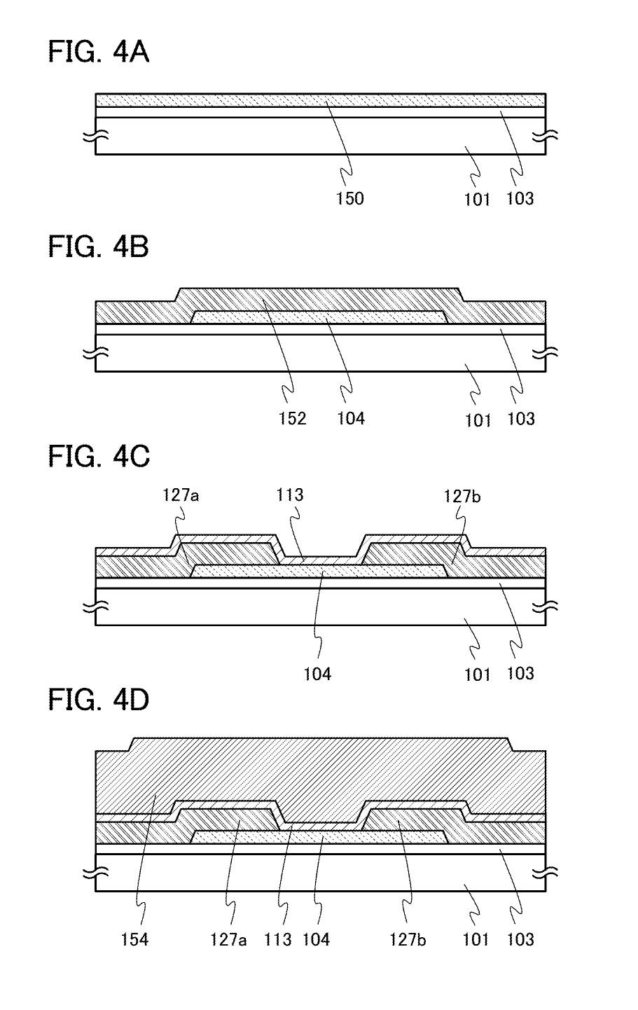

First, the substrate 101 is prepared, the base insulating film 103 is formed over the substrate 101, and an oxide semiconductor film 150 is formed over the base insulating film 103 (see FIG. 4A).

The base insulating film 103 can be formed using any of the materials given above by a chemical vapor deposition (CVD) method, a sputtering method, a molecular beam epitaxy (MBE) method, a pulsed laser deposition (PLD) method, or a laser ablation method.

In this embodiment, an insulating film which contains oxygen in a proportion higher than that of oxygen in the stoichiometric composition is formed as the base insulating film 103. The insulating film containing oxygen in a proportion higher than that of oxygen in the stoichiometric composition can be formed, for example, by injecting oxygen ions by an ion implantation method or an ion doping method into an insulating film that is formed using any of the materials and formation methods given above. Note that oxygen ions may be injected into the insulating film by heat treatment in an atmosphere containing oxygen or plasma treatment.

Thus, in this embodiment, silicon oxynitride containing excessive oxygen is formed to a thickness of 300 nm by a CVD method as the base insulating film 103. Note that in this embodiment, after heat treatment is performed for the purpose of removing hydrogen contained in the base insulating film 103, the silicon oxynitride containing excessive oxygen is formed by injection of oxygen ions.

The oxide semiconductor film 150 is formed over the base insulating film 103 by a sputtering method, a coating method, a pulsed laser deposition method, a laser ablation method, or the like using any of the above materials.

In the case where the oxide semiconductor film 150 is formed by a sputtering method, a power supply device for generating plasma can be an RF power supply device, an AC power supply device, a DC power supply device, or the like as appropriate.

As a sputtering gas, a rare gas (typically argon), an oxygen gas, or a mixed gas of a rare gas and oxygen is used as appropriate. In the case of using the mixed gas of a rare gas and oxygen, the proportion of oxygen is preferably higher than that of a rare gas.

Further, a sputtering target may be appropriately selected in accordance with the composition of the oxide semiconductor film 150 to be formed.

To form the CAAC-OS film as the oxide semiconductor film 150, any of the following methods can be used.

There are the following methods of obtaining the CAAC-OS film. The first method is to form an oxide semiconductor film with a temperature higher than or equal to 200° C. and lower than or equal to 700° C. The second method is a method in which an oxide semiconductor film is formed without application of heat, and then heat treatment is performed at a temperature higher than or equal to 200° C. and lower than or equal to 700° C. The third method is a method in which an oxide semiconductor film with a small thickness is formed; heat treatment is performed at a temperature higher than or equal to 200° C. and lower than or equal to 700° C.; and then another oxide semiconductor film having a larger thickness than the oxide semiconductor film that has been subjected to the heat treatment is formed over the oxide semiconductor film. Note that in the second method, another oxide semiconductor film may be formed and then heat treatment may be performed at a temperature higher than or equal to 200° C. and lower than or equal to 700° C.

Note that the oxide semiconductor film 150 can be formed in a rare gas (typically argon) atmosphere, an oxygen atmosphere, or a mixed atmosphere containing a rare gas and oxygen. The oxide semiconductor film 150 is preferably formed under a condition such that much oxygen is contained (for example, by a sputtering method in an atmosphere where the proportion of oxygen is 100%) so as to be a film containing much oxygen (preferably having a region containing excessive oxygen as compared to the stoichiometric composition of an oxide semiconductor in a crystalline state).

For example, the oxide semiconductor film 150 can be formed of an In—Ga—Zn-based oxide. As a target for forming the In—Ga—Zn-based oxide by a sputtering method, a metal oxide target having a composition of In:Ga:Zn=1:1:1 (atomic ratio) can be used. Further, the material and the composition of the metal oxide target are not limited thereto, and a metal oxide target having a composition of In:Ga:Zn=2:2:1 (atomic ratio) or a metal oxide target having a composition of In:Ga:Zn=3:1:2 (atomic ratio) can be used.

Note that thermal energy which is necessary for forming the CAAC-OS film varies depending on the atomic ratio of the target to be used. For example, in the case where a metal oxide target having a composition of In:Ga:Zn=3:1:2 (atomic ratio) is used, the CAAC-OS film is formed while a substrate over which a film to be formed is heated to approximately 300° C.; in the case where a metal oxide target having a composition of In:Ga:Zn=1:1:1 (atomic ratio) is used, the CAAC-OS film is formed while a substrate over which a film to be formed is heated to approximately 400° C.

The filling factor of the metal oxide target is greater than or equal to 90% and less than or equal to 100%, preferably greater than or equal to 95% and less than or equal to 99.9%. With the use of the metal oxide target having such a high filling rate, the oxide semiconductor film to be formed can be a dense film.

Further, the metal oxide target that can be used for forming the oxide semiconductor film 150 preferably has crystallinity; that is, a single crystalline target, a polycrystalline target, or the like is preferably used. An oxide semiconductor film which is deposited by using a target having crystallinity has crystallinity, and particularly tends to be a CAAC-OS film.

The oxide semiconductor film 150 immediately after being formed is preferably in a supersaturated state in which the proportion of oxygen is higher than that in the stoichiometric composition. For example, when an oxide semiconductor film is formed by a sputtering method, it is preferable that the film be formed in a film formation gas containing a high percentage of oxygen, and it is especially preferable that the film be formed under an oxygen atmosphere (oxygen gas 100%). The deposition under the condition where the proportion of oxygen in a deposition gas is large, in particular, in an atmosphere containing an oxygen gas at 100% can reduce release of Zn from the film even when the deposition temperature is, for example, higher than or equal to 300° C.

It is preferable that a high-purity gas from which an impurity such as hydrogen, water, a hydroxyl group, or hydride is removed be used as a sputtering gas for the formation of the oxide semiconductor film 150.

In forming the oxide semiconductor film 150 by a sputtering method, the substrate 101 is held in a deposition chamber which is maintained under reduced pressure. Then, a sputtering gas from which hydrogen and moisture are removed is introduced into the deposition chamber while moisture remaining therein is removed, and the oxide semiconductor film 150 is formed over the substrate 101 with the use of the above target. In order to remove moisture remaining in the deposition chamber, an entrapment vacuum pump such as a cryopump, an ion pump, or a titanium sublimation pump is preferably used. As an exhaustion unit, a turbo molecular pump to which a cold trap is added may be used. A hydrogen atom, a compound containing a hydrogen atom, such as water (and also preferably a compound containing a carbon atom), or the like is removed from the deposition chamber while reduced pressure is maintained with the cryopump, thereby reducing the concentration of impurities contained in the oxide semiconductor film 150 formed in the deposition chamber.

The base insulating film 103 and the oxide semiconductor film 150 are preferably formed in succession without exposure to the air. By the successive formation of the base insulating film 103 and the oxide semiconductor film 150 without exposure to the air, impurities such as hydrogen and moisture can be prevented from being adsorbed onto a surface of the base insulating film 103.

Further, heat treatment may be performed on the oxide semiconductor film 150 in order to remove excess hydrogen (including water and a hydroxyl group) (to perform dehydration or dehydrogenation treatment). The temperature of the heat treatment is higher than or equal to 300° C. and lower than or equal to 700° C., or lower than the strain point of the substrate. The heat treatment can be performed under reduced pressure, an oxygen atmosphere, a nitrogen atmosphere, a rare gas atmosphere, or the like. Time for the heat treatment can be selected as appropriate. For example, the substrate 101 is put in an electric furnace which is a kind of heat treatment apparatus, and the heat treatment is preferably performed on the oxide semiconductor film 150 at 450° C. under an oxygen atmosphere for one hour.

Note that the heat treatment apparatus is not limited to an electric furnace, and a device for heating an object to be processed by thermal conduction or thermal radiation from a heating element such as a resistance heating element may be used. For example, an RTA (rapid thermal annealing) apparatus such as a GRTA (gas rapid thermal annealing) apparatus, or an LRTA (lamp rapid thermal annealing) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for performing heat treatment using a high-temperature gas. As the high-temperature gas, an inert gas which does not react with an object by heat treatment, for example, nitrogen or a rare gas such as argon is used.

For example, as the heat treatment, GRTA may be performed as follows. The substrate is put in an inert gas heated to a high temperature of 650° C. to 700° C., is heated for several minutes, and is taken out of the inert gas.

Such heat treatment for dehydration or dehydrogenation can be performed anytime after formation of the oxide semiconductor film 150 before formation of a film including a metal element before addition of oxygen into the oxide semiconductor film 150.

In order to improve the field-effect mobility of the transistor 100 by increasing the planarity of a surface of the oxide semiconductor film 150, polishing treatment (e.g., a chemical mechanical polishing (CMP method)), a dry etching method, or plasma treatment is preferably performed so that the base insulating film 103 has an average surface roughness (Ra) within the above range.

As plasma treatment, reverse sputtering in which an argon gas is introduced and plasma is generated can be performed. The reverse sputtering is a method in which voltage is applied to a substrate side with use of an RF power source in an argon atmosphere and plasma is generated in the vicinity of the substrate so that a substrate surface is modified. Note that instead of an argon atmosphere, a nitrogen atmosphere, a helium atmosphere, an oxygen atmosphere, or the like may be used. The reverse sputtering can remove particle substances (also referred to as particles or dust) attached to the surface of the base insulating film 103.

As the planarization treatment, polishing treatment, dry etching treatment, or plasma treatment, may be performed plural times, or these treatments may be performed in combination. In the case where the treatments are performed in combination, the order of steps is not particularly limited and may be set as appropriate depending on the roughness of the surface of the base insulating film 103.

In this embodiment, as the oxide semiconductor film 150, an IGZO film that is a CAAC-OS film is formed to a thickness of 20 nm by a sputtering method using an In—Ga—Zn-based oxide target.

Next, a resist mask is formed over the oxide semiconductor film 150 through a photolithography step and an etching step is performed using the resist mask, so that the oxide semiconductor film 104 is formed. Then, a conductive film 152 is formed over the base insulating film 103 and the oxide semiconductor film 104 (see FIG. 4B).

The mask for forming the oxide semiconductor film 104 can be formed by a printing method such as an inkjet method. By a printing method such as an inkjet method, the mask can be formed without using a photomask and thus the manufacturing cost of the transistor 100 can be reduced. In a photolithography step performed later in the manufacturing process, a mask can be formed by a method using a photomask or a printing method such as an inkjet method.

As the above etching step for forming the oxide semiconductor film 104, wet etching, dry etching, or both of them may be employed. For example, in the case of dry etching, an etching gas can be selected appropriately in accordance with the material of the oxide semiconductor film 150. As an etchant used for wet etching of the oxide semiconductor film 150, a mixed solution of phosphoric acid, acetic acid, and nitric acid, or the like can be used. In addition, ITO07N (produced by KANTO CHEMICAL CO., INC.) may also be used.

Alternatively, it is possible that the oxide semiconductor film 150 is not formed and the oxide semiconductor film 104 is formed by a printing method. Thus, the oxide semiconductor film 104 subjected to element isolation can be directly formed.

The conductive film 152 can be formed using any of the above-described conductive materials by a sputtering method, a CVD method, a vapor deposition method, or the like. Here, the conductive film 152 is formed by stacking a tungsten film having a thickness of 50 nm, an aluminum film having a thickness of 400 nm, and a titanium film having a thickness of 100 nm in this order by a sputtering method.

Next, a mask is formed over the conductive film 152 through a photolithography step. Then, an etching step is performed using the mask, whereby the source electrode 127a and the drain electrode 127b are formed. After that, the gate insulating film 113 is formed over the oxide semiconductor film 104, the source electrode 127a, and the drain electrode 127b (see FIG. 4C).

The etching step performed on the conductive film 152 may be performed with either dry etching or wet etching. Etching conditions of the dry etching (the etching gas, the pressure, the power to be applied, the treatment time, and the like) or etching conditions of the wet etching (the etchant, the solution temperature, the treatment time, and the like) can be selected appropriately depending on the material of the conductive film 152. Here, the source electrode 127a and the drain electrode 127b are formed by processing the tungsten film, the aluminum film, and the titanium film by dry etching.

Note that the source electrode 127a and the drain electrode 127b are formed so that the edge portions thereof have tapered shapes, in which case disconnection of a film to be formed after this step can be inhibited. Note that the tapered shape can be obtained by etching while removing the resist mask.

Note that a distance between the source electrode 127a and the drain electrode 127b corresponds to the channel length of the transistor 100. Thus, in order to make the channel length short, light with a wavelength of 365 nm or less is preferably used as a light source of an exposure device, for the photolithography step performed on the conductive film 152. For example, light having a spectrum of a high pressure mercury lamp such as the i-line (with a wavelength of 365 nm), or light with a wavelength in the range from an ultraviolet light region to a visible light region, such as KrF laser light (with a wavelength of 248 nm) or ArF laser light (with a wavelength of 193 nm), is preferably used.

The gate insulating film 113 can be formed by a sputtering method, a CVD method, a coating method, a printing method, or the like using any of the above-described materials applicable to the base insulating film 103.

Here, silicon oxynitride containing excessive oxygen is formed to a thickness of 20 nm by a CVD method as the gate insulating film 113. Note that in this embodiment, after heat treatment is performed for the purpose of removing hydrogen contained in the gate insulating film 113, the silicon oxynitride containing excessive oxygen is formed by injection of oxygen ions.

A conductive film 154 is formed over the gate insulating film 113 (see FIG. 4D). In a manner similar to the conductive film 152, the conductive film 154 can be formed using any of the above-described conductive materials by a sputtering method, a CVD method, a vapor deposition method, or the like. Here, the conductive film 154 is formed by stacking a tungsten film having a thickness of 100 nm by a sputtering method.

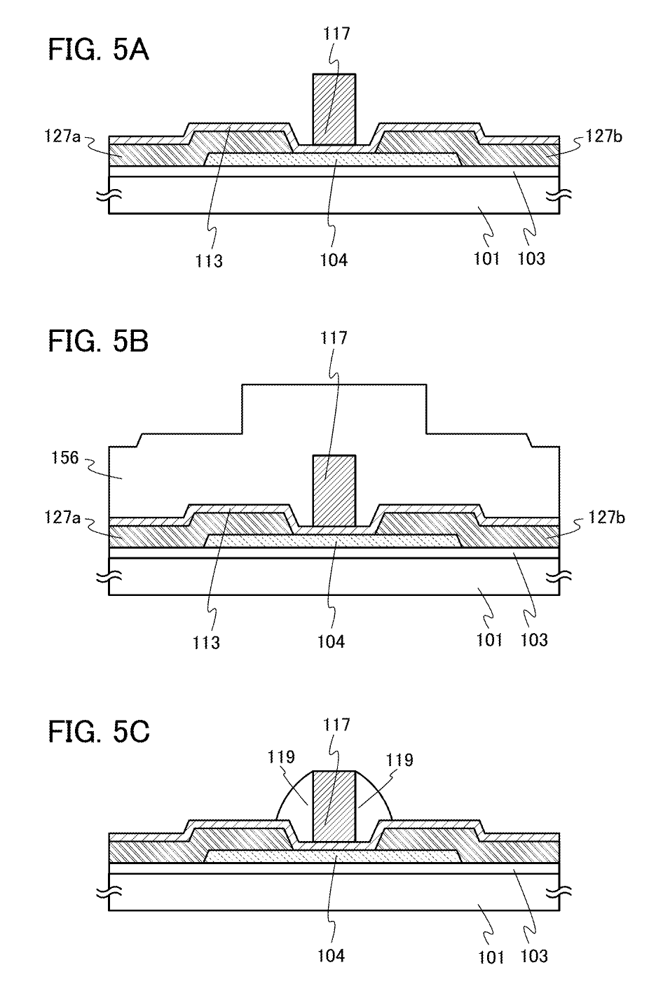

Next, a mask is formed over the conductive film 154 through a photolithography step and then an etching step is performed using the mask, whereby the gate electrode 117 is formed (see FIG. 5A). Note that in view of formation of the sidewall insulating film 119 in a later step, the gate electrode 117 is formed so as to have a taper angle that is as close to perpendicular as possible.

The etching step performed on the conductive film 154 may be performed with either dry etching or wet etching. An etching gas of dry etching or an etchant of wet etching may be selected appropriately depending on the material of the conductive film 154. Here, the gate electrode 117 is formed by processing the tungsten film by dry etching using the mask.

Note that in forming the gate electrode 117, the gate insulating film 113 except a region in contact with the gate electrode 117 can be removed using the gate electrode 117 as a mask and then steps which are described below can be performed, whereby a transistor which has a structure as illustrated in FIG. 1B in which the sidewall insulating film 119 is in contact with the source electrode 127a and the drain electrode 127b can be manufactured.

Next, an insulating film 156 is formed over the gate insulating film 113 and the gate electrode 117 (see FIG. 5B).

The insulating film 156 can be formed by a sputtering method, a CVD method, a coating method, a printing method, or the like using any of the above-described materials applicable to the base insulating film 103. Note that at the time of processing the insulating film 156 into the sidewall insulating film 119 in a later step, the sidewall insulating film 119 is preferably formed to such a thickness that the sidewall insulating film 119 can fill the recessed portion between the gate electrode 117 and the source electrode 127a and the recessed portion between the gate electrode 117 and the drain electrode 127b.

The insulating film 156 is processed by anisotropic etching such as a reactive ion etching (RIE) method, so that the sidewall insulating film 119 which is in contact with the side surface of the gate electrode 117 is formed in a self-aligned manner. Here, since the insulating film 156 is formed using an oxide insulating film, an oxynitride insulating film, or a nitride oxide insulating film, oxygen is supplied to the oxide semiconductor film 104 by heat treatment in the manufacturing process of the transistor 100, so that oxygen vacancies in the oxide semiconductor film 104 can be filled and the electrical characteristics of the transistor 100 can be improved. In the case where a nitride insulating film is used, etching for forming the sidewall insulating film 119 can be performed at a condition where an etching selectivity with the gate insulating film 113 is high, and thus a defect which is generated at the time of formation of the sidewall insulating film 119 can be prevented. Accordingly, the transistor 100 can be manufactured with a high yield.

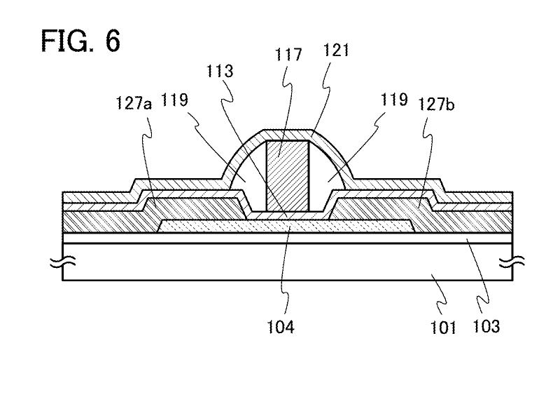

Next, the insulating film 121 is formed over the gate insulating film 113, the gate electrode 117, and the sidewall insulating film 119 (see FIG. 6).

It is preferable that the insulating film 121 be a particularly dense insulating film. The insulating film 121 preferably has a thickness greater than or equal to 5 nm and less than or equal to 200 nm, more preferably greater than or equal to 5 nm and less than or equal to 100 nm. Here, an aluminum oxide film with a thickness of 70 nm is formed as the insulating film 121 by a sputtering method.

Since the sidewall insulating film 119 is provided so as to fill the recessed portion between the gate electrode 117 and the source electrode 127a and the recessed portion between the gate electrode 117 and the drain electrode 127b, the aluminum oxide film formed by a sputtering method can be formed without disconnection.

Therefore, the transistor 100 can be manufactured with a high yield (high productivity).

Next, the interlayer insulating film 123 is formed over the insulating film 121 (see FIG. 3B). The interlayer insulating film 123 can be formed using any of the above-described materials applicable to the base insulating film 103 by a sputtering method, a CVD method, a coating method, a printing method, or the like. In this embodiment, silicon oxynitride is formed to a thickness of 400 nm by a plasma CVD method,

Heat treatment is preferably performed at least after the formation of the insulating film 121. This heat treatment can be performed using the same heating conditions as those of heat treatment which can be performed after the oxide semiconductor film 150 is formed over the base insulating film 103. Owing to this heat treatment, part of oxygen contained in the base insulating film 103 and the gate insulating film 113 can be supplied to the interface between the base insulating film 103 and the oxide semiconductor film 104, the interface between the gate insulating film 113 and the oxide semiconductor film 104, and the oxide semiconductor film 104, whereby the interface state density of each interface can be reduced and the oxygen vacancies in the oxide semiconductor film 104 can be repaired. Accordingly, a semiconductor device having favorable electrical characteristics can be manufactured.

According to the above description, in the transistor 100, the oxide semiconductor film 104 is an oxide semiconductor film that has a reduced hydrogen concentration and less oxygen vacancies and is highly purified, and thus negative shift of the threshold voltage is suppressed. Further, leakage current between the source electrode 127a and the drain electrode 127b, typically an off-state current density (a numerical value obtained by dividing the off-state current by the channel width of the transistor) can be reduced to approximately several yA/um to several zA/um. Further, since a low-resistance region is not provided in the oxide semiconductor film 104 of the transistor 100, the off-state current density of the transistor 100 can be easily reduced to the above range.

Since the negative shift of the threshold voltage is suppressed and the off-state current density can be reduced to the above range in the above manner, the channel length of the transistor 100 can be reduced to less than or equal to 100 nm, for example, can be reduced to 30 nm. Note that even when the channel length is short in the above manner, the thickness of the gate insulating film 113 can be reduced to several tens of nanometers and the off-state current density can be reduced to the above range.

In this manner, according to one embodiment of the present invention, a semiconductor device with favorable electrical characteristics and high performance can be provided. Further, a semiconductor device with favorable electrical characteristics and high performance can be manufactured with a high yield.

Note that the structures, methods, and the like described in this embodiment can be used as appropriate in combination with any of the structures, methods, and the like described in the other embodiments.

### Embodiment 2

In this embodiment, a semiconductor device having a structure which is partly different from that of the semiconductor device described in the above embodiment will be described. Also in this embodiment described below, a transistor is described as a semiconductor device. In this embodiment described below, the drawings (including reference numerals and hatching patterns) and descriptions in the above embodiment are used as appropriate, and points described in the above embodiment are not repeated in some cases.

A transistor 200 described in this embodiment is different from the transistor 100 described in Embodiment 1 in that an oxide semiconductor film includes a first region functioning as a channel formation region, a pair of second regions between which the first region is provided, and a pair of third regions between which the first region and the pair of second regions are provided.

The first region, the pair of second regions, and the pair of third regions can be formed in a self-aligned manner by injection of a dopant using the gate electrode, the source electrode, and the drain electrode as masks.

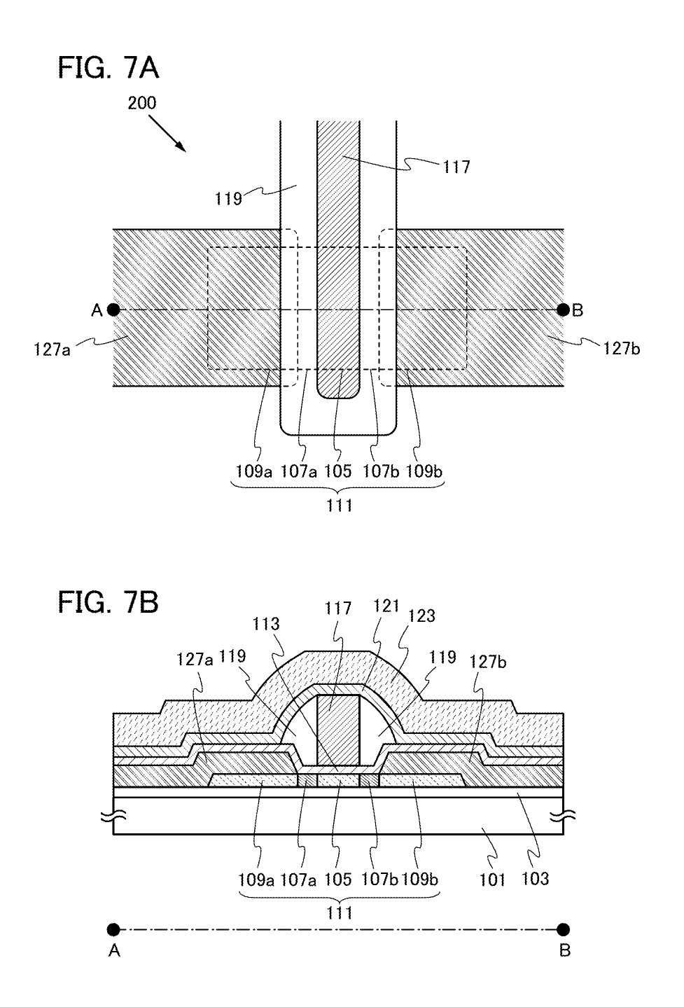

FIGS. 7A and 7B are a top view and a cross-sectional view of the transistor 200. FIG. 7A is a top view of the transistor 200, and FIG. 7B is a cross-sectional view taken along dashed-dotted line A-B in FIG. 7A. Note that in FIG. 7A, some components of the transistor 200 (e.g., the substrate 101, the base insulating film 103, and the gate insulating film 113) are omitted for clarity.

The transistor 200 has the structure of the transistor 100 in which the oxide semiconductor film 104 is replaced with an oxide semiconductor film 111 which includes a first region 105 functioning as a channel formation region, a pair of second regions 107a and 107b between which the first region 105 is provided, and a pair of third regions 109a and 109b between which the first region 105 and the pair of second regions 107a and 107b are provided; and the line width of each of the source electrode 127a and the drain electrode 127b in the channel width direction is larger than the line width of the oxide semiconductor film 111 in the channel width direction (see FIGS. 7A and 7B).

The sidewall insulating film 119 is provided in a manner similar to that in the transistor 100. That is, since the recessed portion between the source electrode 127a and the gate electrode 117 and the recessed portion between the drain electrode 127b and the gate electrode 117 are filled with the sidewall insulating film 119, the step coverage with a film to be formed over the recessed portions is improved and generation of a defect such as a disconnection in the recessed portions is prevented; therefore, the transistor 200 is a transistor having favorable electrical characteristics.

Although the line width of each of the source electrode 127a and the drain electrode 127b in the channel width direction is larger than the line width of the oxide semiconductor film 111 in the channel width direction in the transistor 200, the line width of each of the source electrode 127a and the drain electrode 127b in the channel width direction may be smaller than the line width of the oxide semiconductor film 111 in the channel width direction.

In the oxide semiconductor film 111, the first region 105 overlaps with the gate electrode 117 and does not contain the dopant. Further, the pair of second regions 107a and 107b overlap with the sidewall insulating film 119 positioned between the gate electrode 117 and each of the source electrode 127a and the drain electrode 127b and contain the dopant. The pair of third regions 109a and 109b is in contact with the source electrode 127a and the drain electrode 127b and do not contain the dopant.

Since the pair of second regions 107a and 107b contains the dopant, the pair of second regions 107a and 107b has lower resistance than the first region 105. Although not containing the dopant, the pair of third regions 109a and 109b is in contact with the source electrode 127a and the drain electrode 127b; thus, contact resistance with the pair of third regions 109a and 109b is reduced depending on the material used for the source electrode 127a and the drain electrode 127b, so that regions in the vicinity of interfaces between the pair of third regions 109a and 109b and the source and drain electrodes 127a and 127b have lower resistance than the first region 105. Therefore, at least the pair of third regions 109a and 109b functions as a source region and a drain region.

As described above, since the transistor 200 includes the pair of second regions 107a and 107b, which has lower resistance than the first region 105, and the pair of third regions 109a and 109b, which is in contact with the source electrode 127a and the drain electrode 127b, in addition to the first region 105, the on-state current and the field-effect mobility of the transistor 200 can be increased.

Next, a method for manufacturing the transistor 200 is described. Here, description is made referring to the method for manufacturing the transistor described in the above embodiment.

In the same manner as the transistor 100, a process up to a step of FIG. 5A is performed.

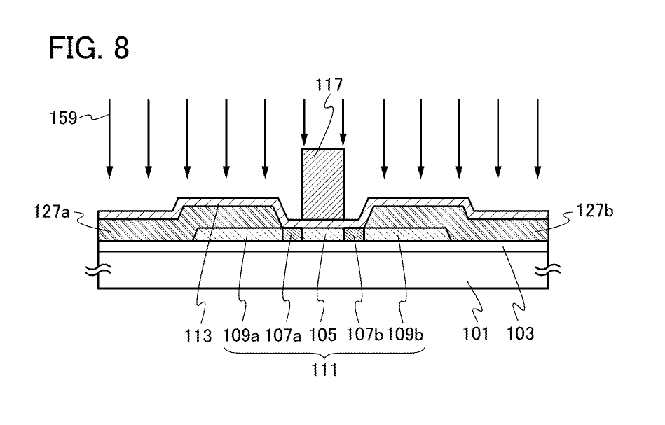

Then, a dopant 159 is injected into the oxide semiconductor film 104 through the gate insulating film 113 with the use of the gate electrode 117, the source electrode 127a, and the drain electrode 127b as masks to form the oxide semiconductor film 111 (see FIG. 8). Note that since the gate electrode 117 is used as a mask in the step of injecting the dopant 159, the first region 105 of the oxide semiconductor film 111 has the same structure as the oxide semiconductor film 104.

Note that in forming the gate electrode 117, the gate insulating film 113 except a region in contact with the gate electrode 117 can be removed using the gate electrode 117 as a mask and then steps which are described below can be performed, whereby a transistor which has a structure as illustrated in FIG. 1B in which the sidewall insulating film 119 is in contact with the source electrode 127a and the drain electrode 127b can be manufactured.

As the dopant 159, one or more kinds of elements selected from elements which reduce the resistance of an oxide semiconductor film can be used; for example, one or more kinds of elements selected from boron, nitrogen, fluorine, aluminum, phosphorus, arsenic, indium, tin, antimony, and rare gas elements can be used.

As a method for injecting the dopant 159 into the oxide semiconductor film 104, an ion implantation method or an ion doping method can be used. Note that, instead of performing an ion implantation method or an ion doping method to inject the dopant 159, plasma treatment or heat treatment may be performed in an atmosphere containing the dopant 159 that reduces the resistance of the oxide semiconductor film 104 to inject the dopant 159 into the oxide semiconductor film 104.

The dopant 159 is injected with injection conditions, e.g., acceleration voltage and dose, set as appropriate. For example, in the case where phosphorus is used as the dopant 159 and phosphorus ions are injected by an ion implantation method, the acceleration voltage can be 30 kV, and the dose can be greater than or equal to 1×10¹³ ions/cm² and less than or equal to 5×10¹⁶ ions/cm², specifically 1×10¹⁵ ions/cm².

Note that heat treatment may be performed after the dopant 159 is injected into the oxide semiconductor film 104 by an ion implantation method. The heat treatment is performed at a temperature higher than or equal to 300° C. and lower than or equal to 700° C., or higher than or equal to 300° C. and lower than the strain point of the substrate 101 in an oxygen atmosphere, a nitrogen atmosphere, reduced pressure, or the air (ultra-dry air). For example, the heat treatment is preferably performed at a temperature higher than or equal to 300° C. and lower than or equal to 450° C. for one hour in an oxygen atmosphere.

In the case where the regions containing the dopant 159 in the oxide semiconductor film 111 are amorphous, hydrogen contained in the first region 105 easily diffuses into the regions containing the dopant 159 during heat treatment performed in any step after the injection of the dopant 159 in the manufacturing process of the transistor 200. Thus, hydrogen in the first region 105 is reduced, whereby the first region 105 is highly purified, and the resistance of the regions containing the dopant 159 is further reduced.

In the case where the oxide semiconductor film 104 is a crystalline oxide semiconductor film, part of the oxide semiconductor film 104 becomes amorphous by the injection of the dopant 159 in some cases. In that case, the crystallinity of the part which has become amorphous can be recovered by heat treatment at a temperature high enough for the region to be crystallized.

The subsequent steps are performed in a manner similar to those in the method for manufacturing the transistor 100 described in the above embodiment, whereby the transistor 200 can be manufactured (see FIGS. 5B and 5C, FIG. 6, and FIG. 7).

Heat treatment is preferably performed at least after the formation of the insulating film 121. The heat treatment can be performed in a manner similar to that of the heat treatment performed after the oxide semiconductor film 150 is formed over the base insulating film 103. Owing to this heat treatment, part of oxygen contained in the base insulating film 103 and the gate insulating film 113 can be supplied to the interface between the base insulating film 103 and the oxide semiconductor film 111 (particularly the first region 105), the interface between the gate insulating film 113 and the oxide semiconductor film 111 (particularly the first region 105), and the oxide semiconductor film 111 (particularly the first region 105) to reduce the interface state density of each interface and can repair the oxygen vacancies in the oxide semiconductor film 111. Accordingly, a semiconductor device with favorable characteristics can be manufactured.

According to the above description, in the transistor 200, the oxide semiconductor film 111 is an oxide semiconductor film that has a reduced hydrogen concentration and less oxygen vacancies and is highly purified, and thus negative shift of the threshold voltage is suppressed. Further, leakage current between the source electrode 127a and the drain electrode 127b, typically an off-state current density (a numerical value obtained by dividing the off-state current by the channel width of the transistor) can be reduced to approximately several yA/μm to several zA/μm.

Since the negative shift of the threshold voltage is suppressed and the off-state current density can be reduced to the above range in the above manner, the channel length of the transistor 200 can be reduced to less than or equal to 100 nm, for example, can be reduced to 30 nm. Note that even when the channel length is short in the above manner, the thickness of the gate insulating film 113 can be reduced to several tens of nanometers and the off-state current density can be reduced to the above range.

As described above, according to one embodiment of the present invention, a semiconductor device with favorable electric characteristics and high performance can be provided. Further, the semiconductor device with favorable electrical characteristic and high performance can be manufactured with a high yield.

### Embodiment 3

In this embodiment, a semiconductor device having a structure which is partly different from that of the semiconductor device described in the above embodiment will be described.

A transistor 300 described in this embodiment is different from the transistor 100 described in Embodiment 1 in that an oxide semiconductor film includes a first region which does not contain a dopant and functions as a channel formation region, a pair of second regions which contain a dopant and between which the first region is provided, and a pair of third regions which contain a dopant and between which the first region and the pair of second regions are provided.

The first region, the pair of second regions, and the pair of third regions can be formed in a self-aligned manner by injection of a dopant through the gate insulating film, the source electrode, and the drain electrode with the use of the gate electrode as a mask.

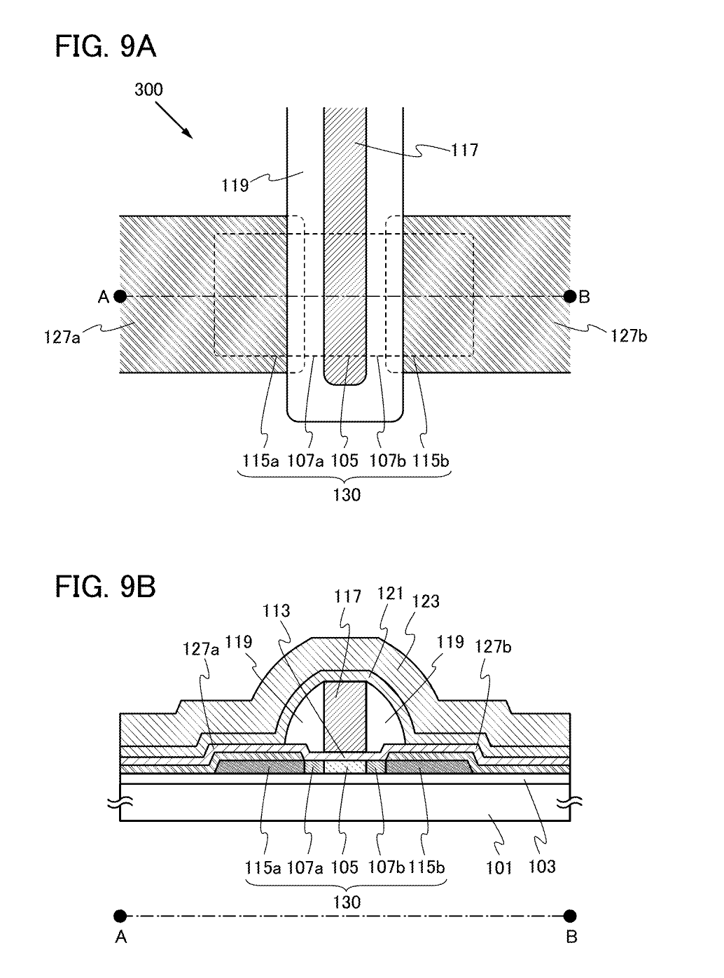

FIGS. 9A and 9B are a top view and a cross-sectional view which illustrate a transistor 300. FIG. 9A is a top view of the transistor 300, and FIG. 9B is a cross-sectional view taken along dashed-dotted line A-B in FIG. 9A. Note that in FIG. 9A, some components of the transistor 300 (e.g., the substrate 101, the base insulating film 103, and the gate insulating film 113) are omitted for simplicity.

The transistor 300 has the structure of the transistor 200 in which the oxide semiconductor film 111 is replaced with an oxide semiconductor film 130 which includes a first region 105 functioning as a channel formation region, a pair of second regions 107a and 107b between which the first region 105 is provided, and a pair of third regions 115a and 115b between which the first region 105 and the pair of second regions 107a and 107b are provided (see FIGS. 9A and 9B).

The sidewall insulating film 119 is provided in a manner similar to those in the transistor 100 and the transistor 200. That is, since the recessed portion between the source electrode 127a and the gate electrode 117 and the recessed portion between the drain electrode 127b and the gate electrode 117 are filled with the sidewall insulating film 119, the step coverage with a film to be formed over the recessed portions is improved and generation of a defect such as a disconnection in the recessed portions is prevented; therefore, the transistor 300 is a transistor having favorable electrical characteristics.

Although the line width of each of the source electrode 127a and the drain electrode 127b in the channel width direction is larger than the line width of the oxide semiconductor film 130 in the channel width direction in the transistor 300, the line width of each of the source electrode 127a and the drain electrode 127b in the channel width direction may be smaller than the line width of the oxide semiconductor film 130 in the channel width direction, as in the transistor 100.

In the oxide semiconductor film 130, the first region 105 overlaps with the gate electrode 117 and does not contain the dopant. Further, the pair of second regions 107a and 107b overlap with the sidewall insulating film 119 positioned between the gate electrode 117 and each of the source electrode 127a and the drain electrode 127b and contain the dopant. The pair of third regions 115a and 115b is in contact with the source electrode 127a and the drain electrode 127b and contains the dopant.

The pair of third regions 115a and 115b has higher dopant concentration and lower resistance than the pair of second regions 107a and 107b. Therefore, the pair of third regions 115a and 115b functions as a source region and a drain region.

As described above, since the resistance of the pair of third regions 115a and 115b in contact with the source electrode 127a and the drain electrode 127b is reduced as in the oxide semiconductor film 130 included in the transistor 300, contact resistance with the source electrode 127a and the drain electrode 127b can be reduced, so that the on-state current and the field-effect mobility of the transistor 300 can be improved.

Further, a channel formation region and low-resistance regions having different dopant concentrations, i.e., the first region 105, the pair of second regions 107a and 107b, and the pair of third regions 115a and 115b, are provided in the oxide semiconductor film 130, whereby electric field concentration in the vicinity of the drain region in particular can be reduced, which can prevent the transistor from being damaged by the electric field concentration.

Next, a method for manufacturing the transistor 300 is described. Here, description is made referring to the method for manufacturing the transistor 100 described in Embodiment 1.

In a manner similar to that used in the method for manufacturing the transistor 100, the base insulating film 103 is formed over the substrate 101 and the oxide semiconductor film 150 is formed over the base insulating film 103 (see FIG. 4A).

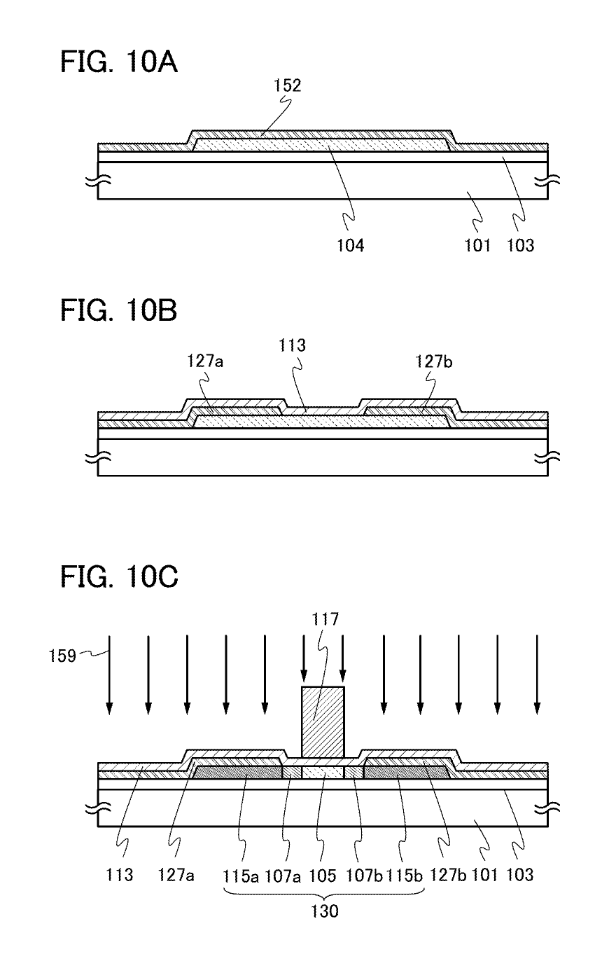

In a manner similar to that used in the method for manufacturing the transistor 100, a photolithography step and an etching step are performed on the oxide semiconductor film 150, so that the oxide semiconductor film 104 is formed. Then, the conductive film 152 is formed over the base insulating film 103 and the oxide semiconductor film 104 (see FIG. 10A).

In this embodiment, since a dopant is to be injected into the oxide semiconductor film 104 through the source electrode 127a and the drain electrode 127b in a later step, the conductive film 152 to be the source electrode 127a and the drain electrode 127b is formed to a smaller thickness than that in the cases of the transistor 100 and the transistor 200. For example, the conductive film 152 is preferably formed to a thickness of 30 nm. It is further preferable that the conductive film 152 be formed using a conductive material through which a dopant easily passes.

Next, in a manner similar to that of the transistor 100, a photolithography step and an etching step are performed on the conductive film 152 to form the source electrode 127a and the drain electrode 127b; then, the gate insulating film 113 is formed over the source electrode 127a and the drain electrode 127b (see FIG. 10B). Subsequently, in a manner similar to that of the transistor 100, the gate electrode 117 is formed over the gate insulating film 113; and the dopant 159 is injected into the oxide semiconductor film 104 through the gate insulating film 113, the source electrode 127a, and the drain electrode 127b with the use of the gate electrode 117 as a mask (see FIG. 10C). A method for injecting the dopant 159 is similar to that in the case of the transistor 200. Note that the injection is performed under treatment conditions which are controlled so that regions of the oxide semiconductor film 104 to be the pair of the third regions 115a and 115b contain a lager amount of the dopant 159 than regions of the oxide semiconductor film 104 to be the pair of second regions 107a and 107b. For example, in the case where an ion implantation method or an ion doping method is used, the injection may be performed by appropriately controlling an accelerating voltage so that the regions to be the pair of the third regions 115a and 115b contain a larger amount of the dopant 159 than the regions to be the pair of second regions 107a and 107b.

Through this step, the oxide semiconductor film 130 including the first region 105, the pair of second regions 107a and 107b, and the pair of third regions 115a and 115b can be formed.

The subsequent steps are performed in a manner similar to those in the method for manufacturing the transistor 100 described in Embodiment 1, whereby the transistor 300 can be manufactured (see FIGS. 5B and 5C, FIG. 6, and FIG. 9).

Note that in the process for manufacturing the transistor 300, the dopant 159 may be injected again after the sidewall insulating film 119 is formed.

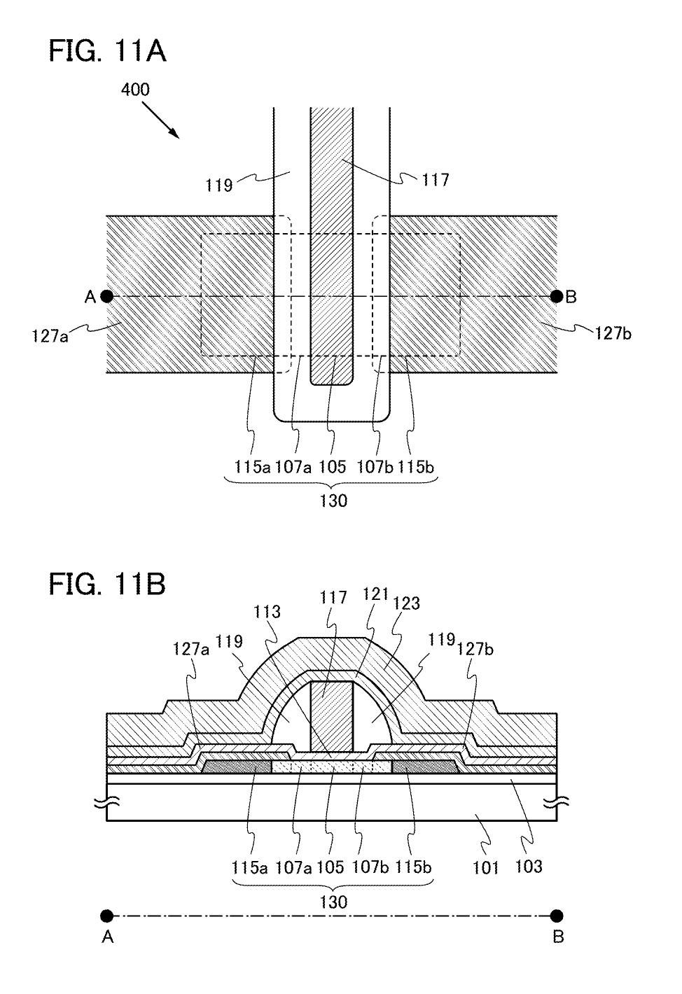

Further, the dopant 159 may be injected using the gate electrode 117 and the sidewall insulating film 119 as masks by utilizing part of the process for manufacturing the transistor 300, whereby a transistor 400 that is one embodiment of the present invention can be manufactured (see FIGS. 11A and 11B).

FIGS. 11A and 11B are a top view and a cross-sectional view of the transistor 400. FIG. 11A is a top view of the transistor 400, and FIG. 11B is a cross-sectional view taken along dashed-dotted line A-B in FIG. 11A. Note that in FIG. 11A, some of components of the transistor 400 (e.g., the substrate 101, the base insulating film 103, and the gate insulating film 113) are omitted for simplicity.

The transistor 400 has a structure in which like the first region 105, the pair of second regions 107a and 107b and part of the pair of third regions 115a and 115b do not contain the dopant 159 in the oxide semiconductor film 130 of the transistor 300.

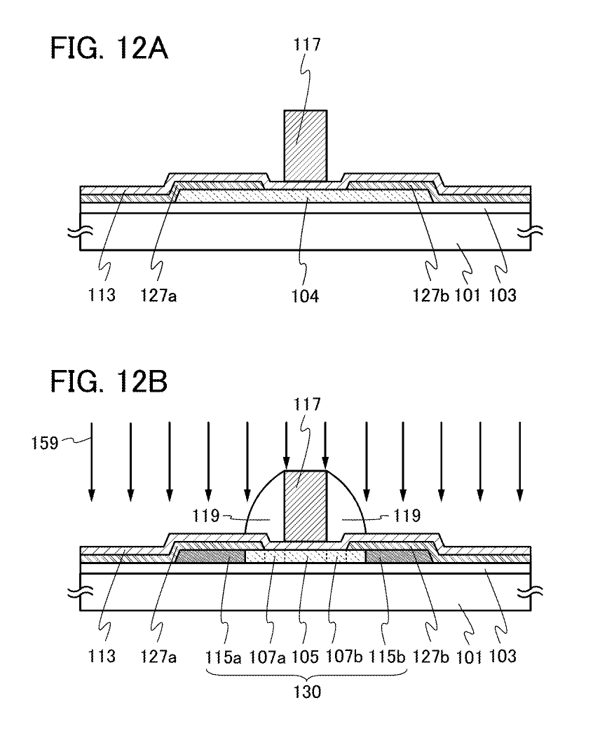

Part of the process for manufacturing the transistor 300 is used for forming the transistor 400, and the steps up to formation of the gate electrode 117 are performed as illustrated in FIG. 12A. Next, unlike in the case of the transistor 300, the sidewall insulating film 119 is formed and then the dopant 159 is injected into the oxide semiconductor film 104 through the gate insulating film 113 with the use of the gate electrode 117 and the sidewall insulating film 119 as masks (see FIG. 12B). The step for forming the sidewall insulating film 119 and the step for injecting the dopant 159 can be performed in the same manner as in the process for forming the transistor 200 described in the above embodiment.

Thus, like in the transistor 200, the negative shift of the threshold voltage is suppressed in the transistor 300 and the transistor 400. Further, leakage current between the source electrode 127a and the drain electrode 127b, typically an off-state current density (a numerical value obtained by dividing the off-state current by the channel width of the transistor) can be reduced to approximately several yA/μm to several zA/μm.

Accordingly, in the transistor 300 and the transistor 400, the channel length can be reduced to less than or equal to 100 nm, for example, can be reduced to 30 nm, as in the transistor 200. Note that even when the channel length is short in the above manner, the thickness of the gate insulating film 113 can be reduced to several tens of nanometers and the off-state current density can be reduced to the above range.

As described above, according to one embodiment of the present invention, a semiconductor device with favorable electric characteristics and high performance can be provided. Further, the semiconductor device with favorable electrical characteristic and high performance can be manufactured with a high yield.

### Embodiment 4

In this embodiment, a semiconductor device having a structure which is partly different from that of the semiconductor device described in the above embodiment will be described.

A transistor described in this embodiment is the one in which side edges of a sidewall insulating film are positioned at a corner portion which is formed by a surface of a source electrode facing a gate electrode and a top surface of the source electrode and at a corner portion which is formed by a surface of a drain electrode facing the gate electrode and a top surface of the drain electrode, as illustrated in FIGS. 2A and 2B.

Further, the sidewall insulating film of the transistor described in this embodiment has a smaller width than the sidewall insulating film of the transistor described in the above embodiment.

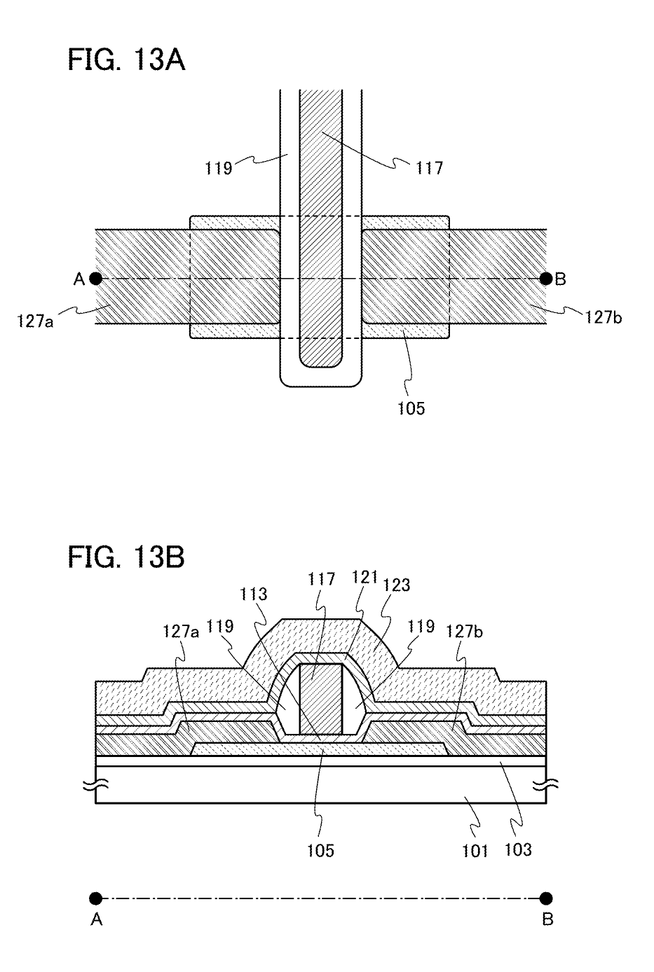

A transistor illustrated in FIGS. 13A and 13B has the structure of the transistor 100 in which the side edges of the sidewall insulating film 119 are provided to be positioned at the corner portion formed by the surface of the source electrode 127a facing the gate electrode 117 and the top surface of the source electrode 127a and at the corner portion formed by the surface of the drain electrode 127b facing the gate electrode 117 and the top surface of the drain electrode 127b. Note that FIG. 13A is a top view of the transistor and FIG. 13B is a cross-sectional view taken along dashed-dotted line A-B in FIG. 13A. Note that in FIG. 13A, some components of the transistor (e.g., the substrate 101, the base insulating film 103, and the gate insulating film 113) are omitted for clarity.

The transistor described in this embodiment can be manufactured according to the process for manufacturing the transistor 100 in which the thickness of an insulating film used for forming the sidewall insulating film 119 and etching conditions of the insulating film are selected appropriately. For example, in forming the insulating film, the thickness of the insulating film is selected appropriately in consideration of the depth of the recessed portion formed between the gate electrode 117 and the source electrode 127a and the depth of the recessed portion formed between the gate electrode 117 and the drain electrode 127b. Then, the etching conditions are selected appropriately in consideration of the thickness of the insulating film and an etching step is performed on the insulating film. In addition, the sidewall insulating film 119 in the transistor described in this embodiment may be formed in such a manner that a sidewall insulating film is formed in a manner similar to that of the transistor 100 (see FIGS. 5B and 5C); after that, plasma treatment (oxygen ashing) is performed in an oxygen atmosphere to reduce the width of the sidewall insulating film.

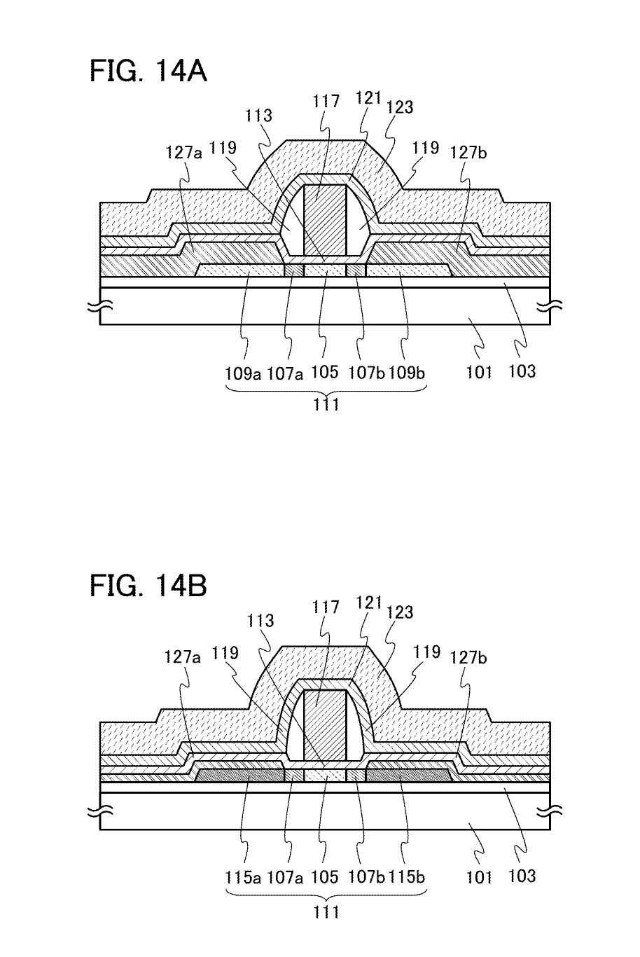

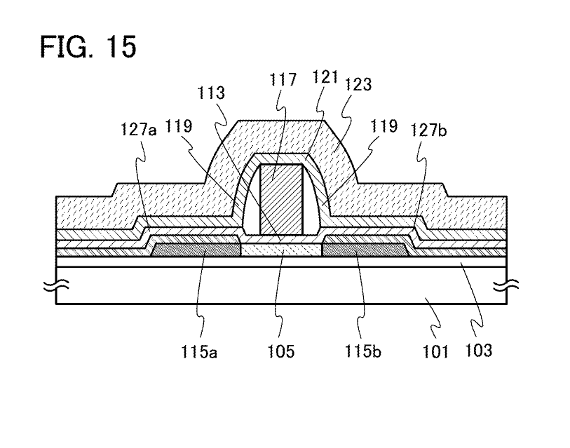

The structure of the sidewall insulating film 119 described in this embodiment is applicable not only to the transistor 100 but also to all of the transistors described in the above embodiments. Thus, cross-sectional views of transistors in a channel length direction are illustrated in FIGS. 14A and 14B and FIG. 15.

FIG. 14A illustrates a transistor obtained by applying the structure of the sidewall insulating film described in this embodiment to the transistor 200. FIG. 14B illustrates a transistor obtained by applying the structure of the sidewall insulating film described in this embodiment to the transistor 300. FIG. 15 illustrates a transistor obtained by applying the structure of the sidewall insulating film described in this embodiment to the transistor 400.

Note that as the transistors illustrated in FIGS. 14A and 14B and FIG. 15, a transistor having a structure like the structure illustrated in FIG. 1B in which the sidewall insulating film 119 is in contact with the source electrode 127a and the drain electrode 127b can be formed by performing a step of removing all the region of the gate insulating film 113 except a region in contact with the gate electrode 117 with the use of the gate electrode 117 as a mask in forming the gate electrode 117.

In the transistors described in this embodiment, the step coverage with a film formed over the recessed portion formed between the gate electrode 117 and the source electrode 127a and the recessed portion formed between the gate electrode 117 and the drain electrode 127b is improved, so that a defect such as disconnection of the film formed over the recessed portion can be suppressed.

As described above, according to one embodiment of the present invention, a semiconductor device with favorable electric characteristics and high performance can be provided. Further, the semiconductor device with favorable electrical characteristic and high performance can be manufactured with a high yield.

### Embodiment 5

In this embodiment, a semiconductor device having a structure which is partly different from that of the semiconductor device described in the above embodiment will be described.

A transistor described in this embodiment is different in the shape of the sidewall insulating film from the transistors described in the above embodiments. Although the transistor 100 described in Embodiment 1 is used as an example in this embodiment, the sidewall insulating film having the shape described in this embodiment is applicable to the transistors in the other embodiments.

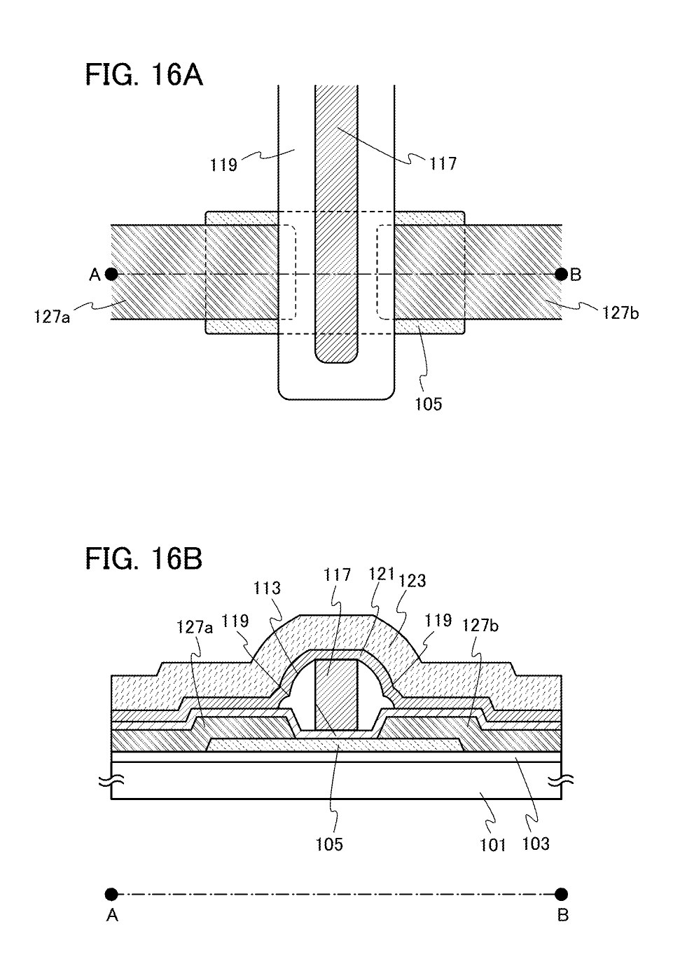

FIG. 16A is a top view of the transistor described in this embodiment, and FIG. 16B is a cross-sectional view taken along dashed-dotted line A-B in FIG. 16A. Note that in FIG. 16A, some of components of the transistor (e.g., the substrate 101, the base insulating film 103, the gate insulating film 113, and the like) are omitted for clarity.

As illustrated in FIGS. 16A and 16B, like the transistor 100, the transistor described in this embodiment includes the base insulating film 103, the oxide semiconductor film 104, the gate insulating film 113, the gate electrode 117, the source electrode 127a, the drain electrode 127b, the sidewall insulating film 119, the insulating film 121, and the interlayer insulating film 123, over the substrate 101. As compared with the transistors described in other embodiments, the sidewall insulating film 119 of the transistor described in this embodiment has a step. The step may be the one which has a curvature radius as illustrated in FIGS. 16A and 16B or may be the one which has a linear shape (not illustrated).

In the transistor described in this embodiment, even in the case where the aspect ratio of the gate electrode 117 is increased, the step coverage with a film to be formed over the recessed portion formed between the gate electrode 117 and the source electrode 127a and the recessed portion formed between the gate electrode 117 and the drain electrode 127b can be improved, so that a defect such as disconnection of the film to be formed over the recessed portion can be suppressed.

Further, it is easier to perform processing so that the sidewall insulating film 119 has a step with a curvature radius than to process so that the sidewall insulating film 119 has a surface with continuous curve like in the transistor 100. That is, it is easier to form the sidewall insulating film 119 described in this embodiment because an allowable range of the process conditions is wide. Therefore, etching conditions (e.g., the etching gas, the pressure, the power to be applied, and the treatment time) for forming the sidewall insulating film 119 may be selected appropriately.

Note that a transistor having a structure like the structure illustrated in FIG. 1B in which the sidewall insulating film 119 is in contact with the source electrode 127a and the drain electrode 127b can be formed by performing a step of removing all the region of the gate insulating film 113 except a region in contact with the gate electrode 117 with the use of the gate electrode 117 as a mask in forming the gate electrode 117.

As described above, according to one embodiment of the present invention, a semiconductor device with favorable electric characteristics and high performance can be provided. Further, the semiconductor device with favorable electrical characteristic and high performance can be manufactured with a high yield.

### Embodiment 6

In this embodiment, a semiconductor device that is one embodiment of the present invention is described. The semiconductor device described in this embodiment is a memory element (memory cell) which includes the transistor described in any of the above embodiments. Thus, the reference numerals described in the above embodiments are also used for the semiconductor device.

The semiconductor device includes a first transistor formed using a single crystal semiconductor substrate, a second transistor formed using a semiconductor film, and a capacitor. The second transistor and the capacitor are provided above the first transistor with an insulating film positioned therebetween.

Semiconductor materials and structures of the first transistor and the second transistor, which are stacked, may be the same as or different from each other. Described here is an example in which transistors with materials and structures suitable for a circuit of the semiconductor device are used as the first transistor and the second transistor.

Any of the transistors described in the above embodiments can be used as the second transistor. Note that the layered structure and connection relations of the first transistor and the capacitor are changed as appropriate depending on the structure of the transistor used as the second transistor. In this embodiment, an example in which the transistor 200 is used as the second transistor is described.

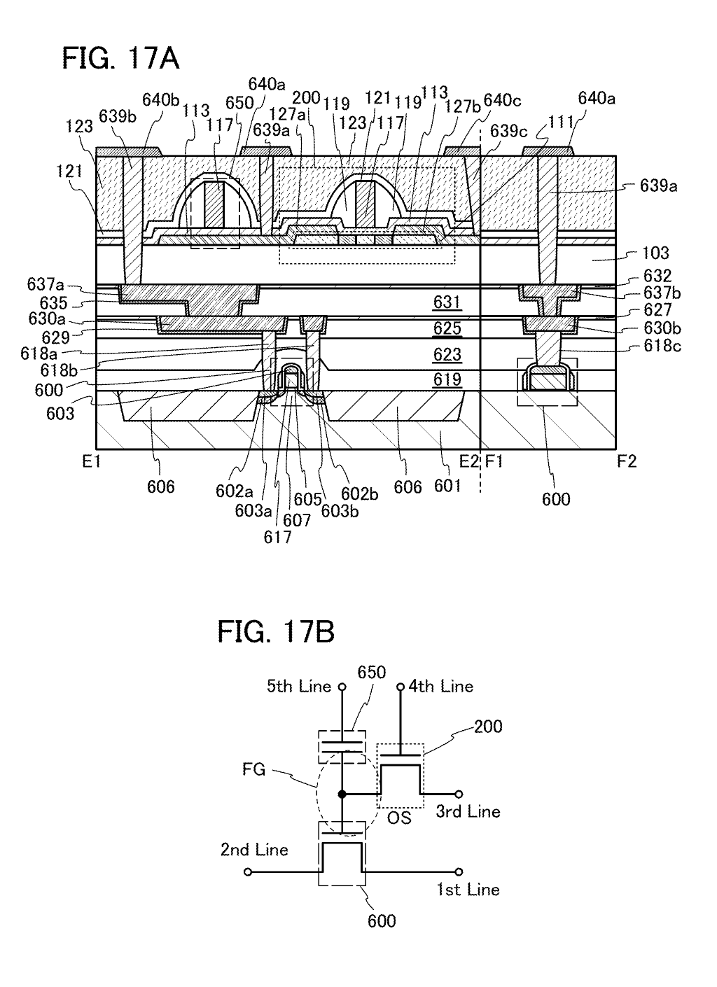

FIG. 17A is a cross-sectional view of the semiconductor device. A cross section along E1-E2 in FIG. 17A is parallel to the channel length direction of the first transistor and the second transistor, and a cross section along F1-F2 in FIG. 17A is perpendicular to the channel length direction of the first transistor.

FIG. 17B illustrates an example of a circuit diagram of the semiconductor device. “OS” in FIG. 17B indicates that the transistor described in the above embodiments can be applied to the transistors denoted by “OS” in the semiconductor device.

The semiconductor device illustrated in FIGS. 17A and 17B includes a transistor 600 including a first semiconductor material in a lower portion, and the transistor 200 including a second semiconductor material and a capacitor 650 in an upper portion. Such materials and structures are suitable for the semiconductor device. In this embodiment, the first semiconductor material is a semiconductor material other than an oxide semiconductor, and the second semiconductor material is an oxide semiconductor. As the semiconductor material other than an oxide semiconductor, for example, silicon, germanium, silicon germanium, silicon carbide, gallium arsenide, or the like can be used, and a single crystal semiconductor is preferably used. A transistor including such a semiconductor material can operate at sufficiently high speed. Alternatively, an organic semiconductor material or the like may be used as the semiconductor material other than an oxide semiconductor. On the other hand, a transistor including an oxide semiconductor enables charge to be held for a long time owing to its characteristics. Note that the transistor 600 and the transistor 200 are each an n-channel transistor.

The transistor 600 includes a channel formation region 607 provided in the substrate 601 containing a semiconductor material (e.g., silicon), impurity regions 602a and 602b provided so that the channel formation region 607 is provided therebetween, intermetallic compound regions 603a and 603b in contact with the impurity regions 602a and 602b, a gate insulating film 605 provided over the channel formation region 607, and a gate electrode 617 and a gate electrode 603 provided over the gate insulating film 605. Note that the intermetallic compound regions 603a and 603b are formed using a silicide (salicide), for example. The gate electrode 603 can be formed in the same process as the intermetallic compound regions 603a and 603b. Further, in the transistor 600, a gate electrode can have, but is not limited to, a stacked structure of the gate electrode 617 including a first material for increasing processing accuracy and the gate electrode 603 including a second material for decreasing the resistance as a wiring; the material, the number of stacked layers, the shape, or the like can be adjusted as appropriate for required specifications.

As the substrate 601 containing a semiconductor material, a single crystal semiconductor substrate or a polycrystalline semiconductor substrate of silicon, silicon carbide, or the like; a compound semiconductor substrate of silicon germanium or the like; an SOT substrate; or the like can be used. Note that although the term “SOT substrate” generally means a substrate in which a silicon semiconductor film is provided over an insulating surface, the term “SOT substrate” in this specification and the like also includes a substrate in which a semiconductor film formed using a material other than silicon is provided over an insulating surface. That is, a semiconductor layer included in the “SOT substrate” is not limited to a silicon semiconductor film. Moreover, the SOT substrate can be a substrate having a structure where a semiconductor film is provided over an insulating substrate such as a glass substrate with an insulating film provided therebetween.

As a method of forming the SOT substrate, any of the following methods can be used: a method in which oxygen ions are implanted into a mirror-polished wafer and then heating is performed at a high temperature, whereby an oxide layer is formed at a certain depth from a surface of the wafer and a defect caused in the surface layer is eliminated; a method in which a semiconductor substrate is separated by utilizing a phenomenon in which microvoids formed by hydrogen ion irradiation grow because of heat treatment; a method in which a single crystal semiconductor film is formed over an insulating surface by crystal growth; and the like.

For example, ions are added through one surface of a single crystal semiconductor substrate, an embrittlement layer is formed at a certain depth from the surface of the single crystal semiconductor substrate, and an insulating film is formed over one of the surface of the single crystal semiconductor substrate and an element substrate. Heat treatment is performed in a state where the single crystal semiconductor substrate and the element substrate are bonded to each other with the insulating film positioned therebetween, so that a crack is generated in the embrittlement layer and the single crystal semiconductor substrate is separated along the embrittlement layer. Accordingly, a single crystal semiconductor layer, which is separated from the single crystal semiconductor substrate, is formed as a semiconductor layer over the element substrate. An SOI substrate formed by the above method can also be favorably used.

The transistor 600 including a single crystal semiconductor substrate can operate at high speed. Thus, when the transistor 600 is used as a reading transistor, data can be read at a high speed.

Since the transistor 600 is an n-channel transistor, a dopant (e.g., phosphorus or arsenic) for making the transistor 600 function as an n-channel transistor is injected to the impurity regions 602a and 602b.

Over the substrate 601, an element isolation insulating film 606 is provided so as to surround the transistor 600. Note that for high integration, it is preferable that the transistor 600 not be provided with a sidewall insulating film. On the other hand, when the electric characteristics of the transistor 600 have priority, a sidewall insulating film may be formed on a side surface of the gate electrode 617 so that the impurity regions include regions having different impurity concentrations (see FIG. 17A).

The use of the element isolation insulating film 606 can reduce the generation of a bird's beak in an element isolation region, which is caused in an LOCOS element isolation method, and can reduce the size of the element isolation region. On the other hand, in a semiconductor device that is not required to be structurally miniaturized or downsized, the element isolation insulating film 606 is not necessarily formed, and an element isolation means such as LOCOS can be used.

A plurality of insulating films are provided so as to cover the transistor 600. In this embodiment, insulating films 619, 623, 625, and 631 and the base insulating film 103 functioning as a base insulating film of the transistor 200 are provided.

The transistor 600 is covered with the insulating film 619. The insulating film 619 can function as a protective film and can prevent impurities from entering the channel formation region 607 from the outside. In addition, when the insulating film 619 is formed using a material such as silicon nitride by a CVD method, in the case where single crystal silicon is used for the channel formation region 607, dehydrogenation can be performed by heat treatment. Further, when an insulating film having stress is used as the insulating film 619, distortion can be given to a semiconductor material included in the channel formation region and thus the field-effect mobility of the transistor 600 can be improved.

The impurity region 602a functioning as a source of the transistor 600 and the intermetallic compound region 603a are connected to a wiring 640b through a contact plug 618a which penetrates at least the insulating film 619, the insulating film 623, and the insulating film 625; a wiring 630a; a wiring 637a; and a contact plug 639b which penetrates at least the insulating film 103, the insulating film 113, the insulating film 121, and the insulating film 123 (2nd Line in FIG. 17B). The impurity region 602b functioning as a drain of the transistor 600 and the intermetallic compound region 603b are connected to the wiring 630a through a contact plug 618b which penetrates at least the insulating film 619, the insulating film 623, and the insulating film 625. Further, although not illustrated, like the impurity region 602a and the intermetallic compound region 603a, the impurity region 602b and the intermetallic compound region 603b are connected to a wiring which is provided above the transistor 200 through the wiring 637 and the contact plug 639b (1st Line in FIG. 17B).

Here, the contact plugs 618a and 618b also function as a source electrode and a drain electrode of the transistor 600. In addition, impurity regions which are different from the impurity regions 602a and 602b are provided between the impurity regions 602a and 602b and the channel region. The impurity regions function as LDD regions or extension regions for controlling the distribution of an electric field in the vicinity of the channel formation region, depending on the concentration of an impurity introduced thereto. Sidewall insulating films formed of a nitrogen insulating film are provided on sidewalls of the gate electrode 617 and the gate electrode 603 with an insulating film such as a thermal oxidation film provided therebetween. By using the insulating film and the sidewall insulating films, the LDD regions or extension regions can be formed.

The transistor 200 including the second semiconductor material and the capacitor 650 are formed to be electrically connected to the transistor 600 including the first semiconductor material in the lower layer, according to the circuit configuration illustrated in FIG. 17B. FIG. 17A illustrates an example in which the gate electrodes 617 and 603 of the transistor 600 are electrically connected to the source electrode 127a of the transistor 200.

The gate electrodes 617 and 603 of the transistor 600 are electrically connected to the source electrode 127a of the transistor 200 through a contact plug 618c which penetrates at least the insulating film 619, the insulating film 623, and the insulating film 625; the wiring 630b; the wiring 637b; a contact plug 639a which penetrates at least the base insulating film 103, the gate insulating film 113, the insulating film 121, and the interlayer insulating film 123; and a wiring 640a which is formed above the transistor 200. Note that the contact plug 618c also functions as a gate electrode of the transistor 600.

As each of the insulating films 619, 623, and 625, typically, an inorganic insulating film such as a silicon oxide film, a silicon oxynitride film, an aluminum oxide film, an aluminum oxynitride film, a silicon nitride film, an aluminum nitride film, a silicon nitride oxide film, or an aluminum nitride oxide film can be used. Further, it is possible to use an insulating film formed of borophosphosilicate glass (BPSG), phosphosilicate glass (PSG), silicon oxide to which carbon is added (SiOC), silicon oxide to which fluorine is added (SiOF), silicon oxide made from Si(OC₂H₅)₄ (tetraethylorthosilicate (TEOS)), hydrogen silsesquioxane (HSQ), methyl silsesquioxane (MSQ), or an organic-polymer-based material such as organosilicate glass (OSG). In particular, in the case of advancing miniaturization of the semiconductor device, parasitic capacitance between wirings is significant and signal delay is increased. Therefore, the relative permittivity of silicon oxide (k=4.0 to 4.5) is too high, and it is preferable to use a material with k=3.0 or less. In addition, since CMP treatment is performed after the wirings are embedded in the insulating films, the insulating films need to have high mechanical strength. As long as their mechanical strength can be secured, the insulating films can be made porous to have a lower dielectric constant. The insulating film 631 is formed by a sputtering method, a CVD method, a coating method including a spin coating method (also referred to as spin on glass (SOG)), or the like.

An insulating film 627 and an insulating film 632 may be provided over the insulating film 625 and the insulating film 631, respectively. The insulating film 627 and the insulating film 632 function as etching stopper films against polishing treatment or etch-back treatment which is to be performed at the time of forming a contact plug and a wiring described later.

The contact plug 618c and the contact plug 639a can be each formed in such a manner that a conductive film is formed using a conductive material and processed into a desired shape and polishing treatment or etch-back treatment is performed to expose a top surface of the processed conductive film.

The wiring 630a and the wiring 630b are embedded in the insulating film 625. The wiring 637a and the wiring 630b are embedded in the insulating film 631. For the wiring 630a, the wiring 630b, the wiring 637a, and the wiring 637b, it is preferable to use a low-resistance conductive material such as copper or aluminum. By using a low-resistance conductive material, RC delay of signals transmitted through the wiring 630 a, the wiring 630b. the wiring 637a and the wiring 637b can be reduced. In the case where copper is used for the wiring 630a, the wiring 630b, the wiring 637a, and the wiring 637b, a barrier film 629 and a barrier film 635 are preferably formed to prevent diffusion of copper into the channel formation region of the transistor 600. The barrier films can each be formed using a film of tantalum nitride, a stacked-layer film of tantalum nitride and tantalum, a film of titanium nitride, a stacked-layer film of titanium nitride and titanium, or the like for example, but are not limited to the films of these materials as long as their function of preventing diffusion of a wiring material and their adhesion to the wiring material, a base film, or the like are secured. The barrier film 629 and the barrier film 635 may be formed as layers that are separate from the wiring 630a, the wiring 630b, the wiring 637a and the wiring 637b, or may be formed in such a manner that a barrier film material contained in a wiring material is separated out by heat treatment to the inner walls of openings provided in the insulating film 625 and the insulating film 631.

The wiring 637a and the wiring 637b each include a wiring portion in an upper portion and a via hole portion in a lower portion as illustrated in FIG. 17A. The via hole portions in the lower portion are connected to the wirings 630a and the wiring 630b in a layer provided therebelow. The wiring 637a and the wiring 637b having the structure described above can be formed by a so-called dual damascene method or the like. Wirings in upper and lower layers may be connected using a contact plug instead of the dual damascene method.

The transistor 200 and the capacitor 650 are formed over the insulating film 632. The transistor 200 can be manufactured in accordance with the description in any of the above embodiments (see FIGS. 4A to 4D, FIGS. 7A and 7B, and FIG. 8).

The wirings 640a, 640b, and 640c can be formed similarly to the wiring 630a and the wiring 637a. Note that the wiring 640c is electrically connected to the drain electrode 127b of the transistor 200 through a contact plug 639c which is provided to penetrate the gate insulating film 113, the insulating film 121, and the interlayer insulating film 123 (3rd Line in FIG. 17B).

In the semiconductor device of this embodiment, the capacitor 650 is manufactured by utilizing the manufacturing process of the transistor 200; thus, the capacitor 650 can be formed over the same plane as the transistor 200. Accordingly, additional steps for manufacturing the capacitor 650 can be omitted, which leads to an improvement in productivity and a reduction in manufacturing cost of the semiconductor device.

In the capacitor 650, the source electrode 127a of the transistor 200 is used as one electrode, the gate insulating film 113 of the transistor 200 is used as a dielectric, and the gate electrode 117 of the transistor 200 is used as the other electrode (4th Line and 5th Line in FIG. 17B). Note that in the case where the sidewall insulating film 119 of the transistor 200 is formed in a self-aligned manner, an insulating film similar to the sidewall insulating film 119 of the transistor 200 is formed on the other electrode of the capacitor 650.

Further, the other electrode of the capacitor 650 may be provided to overlap with the gate electrode 617 of the transistor 600. Such a layout enables an increase in integration degree of the semiconductor device (memory element). For example, an area occupied by the memory element can be 15F² to 25F² where the minimum feature size is F.

Since the transistor 200 includes the oxide semiconductor film 111 which includes the pair of second regions 107a and 107b having lower resistance than the first region 105 functioning as a channel formation region and the pair of third regions 109a and 109b in contact with the source electrode 127a and the drain electrode 127b with the first region 105 provided in the channel length direction between those pair of regions, the transistor 200 has excellent on-state characteristics (e.g., high on-state current and high field-effect mobility), which enables high-speed operation and high-speed response of the transistor 200. Note that one of or both the pair of second regions 107a and 107b and the pair of third regions 109a and 109b function as a source region and a drain region.

In the base insulating film 103, an oxygen excess region can be provided close to the oxide semiconductor film 111. Thus, oxygen can be efficiently supplied from the oxygen excess region to the oxide semiconductor film 111. The supply of oxygen can be promoted by heat treatment.

Further, regarding the base insulating film 103, instead of being provided in the region in the vicinity of the interface in contact with the oxide semiconductor film 111 that needs to be supplied with oxygen, the oxygen excess region may be provided in the vicinity of the bottom surface of the base insulating film 103, which is apart from the top surface of the base insulating film 103. Such a structure can suppress unnecessary release of oxygen from the top surface of the base insulating film 103 even when heat treatment is performed in particular, so that the base insulating film 103 can be kept in an oxygen excess state.

Accordingly, it is possible to efficiently repair oxygen vacancies in the oxide semiconductor film 111 and at the interface of the oxide semiconductor film 111 in the transistor 200.

In addition, since the insulating film 121 is provided over the gate insulating film 113, the gate electrode 117, and the sidewall insulating film 119 and has a function of preventing impurities such as hydrogen contained in the air to pass therethrough, the transistor 200 and the capacitor 650 have favorable reliability. Accordingly, the semiconductor device of this embodiment has excellent reliability.

Through the above process, the semiconductor device including the transistor 600, the transistor 200, and the capacitor 650 can be manufactured. The transistor 200 includes the oxide semiconductor film 111 in which at least the first region 105 is highly purified and oxygen vacancies are repaired, and thus fluctuation in the electrical characteristics of the transistor is suppressed. Accordingly, fluctuation in the electrical characteristics can be suppressed even in the semiconductor device.

In the case where a capacitor is not needed, a structure without the capacitor 650 can also be employed for the semiconductor device of this embodiment.

FIG. 17B is an example of a diagram of a circuit including the semiconductor device as a memory cell. In FIG. 17B, one of a source electrode and a drain electrode of the transistor 200 is electrically connected to one electrode of the capacitor 650, and the gate electrode of the transistor 200. A first wiring (1st Line, also referred to as a source line) is electrically connected to a source electrode of the transistor 600. A second wiring (2nd Line, also referred to as a bit line) is electrically connected to a drain electrode of the transistor 600. A third wiring (3rd line, also referred to as a first signal line) is electrically connected to the other of the source electrode and the drain electrode of the transistor 200. A fourth wiring (4th line, also referred to as a second signal line) is electrically connected to the gate electrode of the transistor 200. A fifth wiring (5th Line, also referred to as a word line) is electrically connected to the other electrode of the capacitor 650.

The transistor 200 including an oxide semiconductor has an extremely small off-state current; therefore, the potential of a node (hereinafter, a node FG) where the one of the source electrode and the drain electrode of the transistor 200, the one electrode of the capacitor 650, and the gate electrode of the transistor 600 are electrically connected to one another can be held for an extremely long time. The capacitor 650 facilitates holding of electric charge supplied to the node FG and reading of the held data.

When data is stored in the semiconductor device (writing), first, the potential of the fourth wiring is set to a potential at which the transistor 200 is turned on, whereby the transistor 200 is turned on. Thus, the potential of the third wiring is supplied to the node FG and a predetermined amount of electric charge is accumulated in the node FG. Here, electric charge for applying either two different potential levels (hereinafter referred to as Low-level charge and High-level charge) is given to the node FG. After that, the potential of the fourth wiring is set to a potential at which the transistor 200 is turned off; thus, the predetermined amount of electric charge is held in the node FG. The predetermined amount of electric charge is thus accumulated and held in the node FG, whereby the memory cell can store data.

Since the off-state current of the transistor 200 is extremely small, the electric charge supplied to the node FG is held for a long time. This can remove the need of refresh operation or drastically reduce the frequency of the refresh operations, which leads to a sufficient reduction in power consumption. Moreover, stored data can be stored for a long time even when power is not supplied.

When stored data is read out (reading), an appropriate potential (reading potential) is supplied to the fifth wiring while a predetermined potential (fixed potential) is supplied to the first wiring, whereby the transistor 600 changes its state depending on the amount of charge held in the node FG. This is because in general, when the transistor 600 is an n-channel transistor, an apparent threshold value Vₜₕ_{_{—}}_{H} of the transistor 600 in the case where High-level charge is held in the node FG is lower than an apparent threshold value Vₜₕ_{_{—}}_{L} of the transistor 200 in the case where Low-level charge is held in the node FG. Here, an apparent threshold value refers to the potential of the fifth line which is needed to turn on the transistor 200. Thus, by setting the potential of the fifth wiring to a potential Vₒ which is between Vₜₕ_{_{—}}_{H} and Vₜₕ_{_{—}}_{L}, electric charge held in the node FG can be determined. For example, in the case where High-level charge is given in writing, when the potential of the fifth line is set to V₀ (>Vₜₕ_{_{—}}_{H}), the transistor 200 is turned on. In the case where Low-level charge is given in writing, even when the potential of the fifth wiring is set to V₀ (<Vₜₕ_{_{—}}_{L}), the transistor 600 remains in an off state. In such a manner, by controlling the potential of the fifth wiring and determining whether the transistor 600 is in an on state or off state (reading out the potential of the second wiring), stored data can be read out.

Further, in order to rewrite stored data, a new potential is applied to the node FG that is holding the predetermined amount of electric charge given in the above writing, so that the charge of the new data is held in the node FG. Specifically, the potential of the fourth wiring is set to a potential at which the transistor 200 is turned on, whereby the transistor 200 is turned on. The potential of the third wiring (a potential of new data) is applied to the node FG, and the predetermined amount of charge is accumulated in the node FG. After that, the potential of the fourth wiring is set to a potential at which the transistor 200 is turned off, whereby the transistor 200 is turned off. Thus, charge of the new data is held in the node FG. In other words, while the predetermined amount of charge given in the first writing is held in the node FG, the same operation (a second writing) as in the first writing is performed, whereby the stored data can be overwritten.

The off-state current of the transistor 200 described in this embodiment can be sufficiently reduced by using the oxide semiconductor film 111 in which at least the first region 105 is highly purified and whose oxygen vacancies are repaired in the transistor 200. Further, with the use of such a transistor, a semiconductor device in which stored data can be held for an extremely long time even when power is not supplied can be provided.

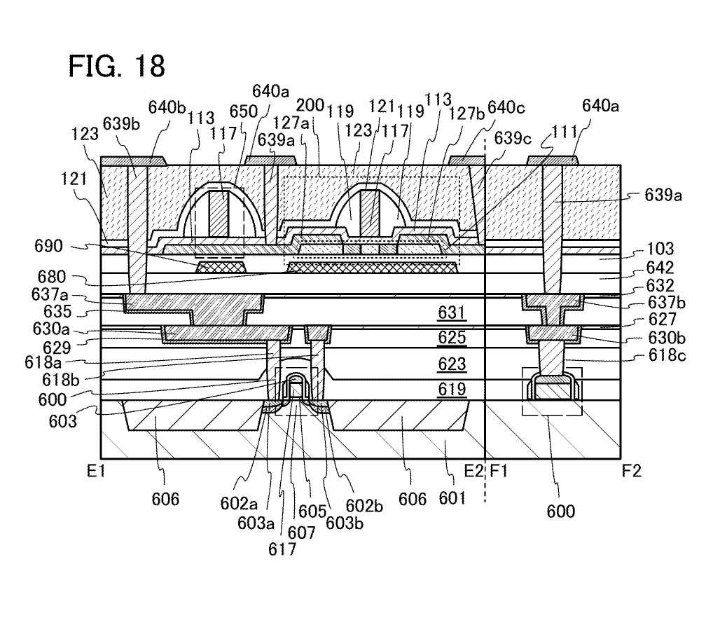

Note that the memory element illustrated in FIGS. 17A and 17B is merely one example, and thus the structure of the memory element described in this embodiment is not limited to that illustrated in FIGS. 17A and 17B. For example, as illustrated in FIG. 18, a conductive film for controlling the electrical characteristics of the second transistor can be provided between the first transistor and the second transistor. In other words, as the second transistor, a transistor in which a conductive film is provided on a side opposite to that of the gate electrode with the oxide semiconductor film positioned therebetween can be used.

In a memory element illustrated in FIG. 18, a conductive film 680 is provided to be sandwiched between an insulating film 642 and the base insulating film 103 and to overlap with the oxide semiconductor film 111 (at least the first region 105) of the transistor 200. A conductive film 690 can be formed in the same step as the conductive film 680 and is provided to overlap with the source electrode 127a with the base insulating film 103 positioned therebetween. The other structures except those described above are the same as those of the memory element illustrated in FIGS. 17A and 17B. Note that an insulating film which is applicable to the insulating film 619 of the transistor 600 or the like can be used as the insulating film 642.

The conductive film 680 and the conductive film 690 can be each formed with a single-layer structure or a stacked-layer structure of two or more layers using a conductive material which is applicable to the gate electrode 117 of the transistor 200. In particular, as the conductive film 680 and the conductive film 690, it is preferable to use a conductive film which has a work function of 4.5 eV or higher, preferably 5 eV or higher, further preferably 5.5 eV or higher, and has higher electron affinity than an oxide semiconductor. As the conductive film, an oxynitride semiconductor film or a metal nitride film which is given as an example in the description of the gate electrode 117 can be used.

In the memory element illustrated in FIG. 18, it is possible to supply a desire potential to the conductive film 680 and the conductive film 690.

In the memory element illustrated in FIG. 18, negative shift of the threshold voltage of the transistor 200 can be suppressed by supplying a fixed potential such as a ground potential to the conductive film 680, or the on-state current of the transistor 200 can be increased by supplying, to the conductive film 690, a signal which synchronizes with a signal supplied to the gate electrode 117.

Further, in the memory element illustrated in FIG. 18, in addition to the capacitor 650, a capacitor can be formed using the conductive film 690, the base insulating film 103, and the one electrode of the capacitor 650 (source electrode 127a). Therefore, by supplying as appropriate a potential (a fixed potential such as a ground potential) to the conductive film 690, the one electrode of the capacitor 650, and the other electrode of the capacitor 650 (gate electrode 117), the capacity of the memory element illustrated in FIG. 18 can be increased.

As described above, a high-performance semiconductor device can be provided by using any of the transistors described in the above embodiments.

Note that the structures, methods, and the like described in this embodiment can be combined as appropriate with any of the structures, methods, and the like described in the other embodiments.

### Embodiment 7

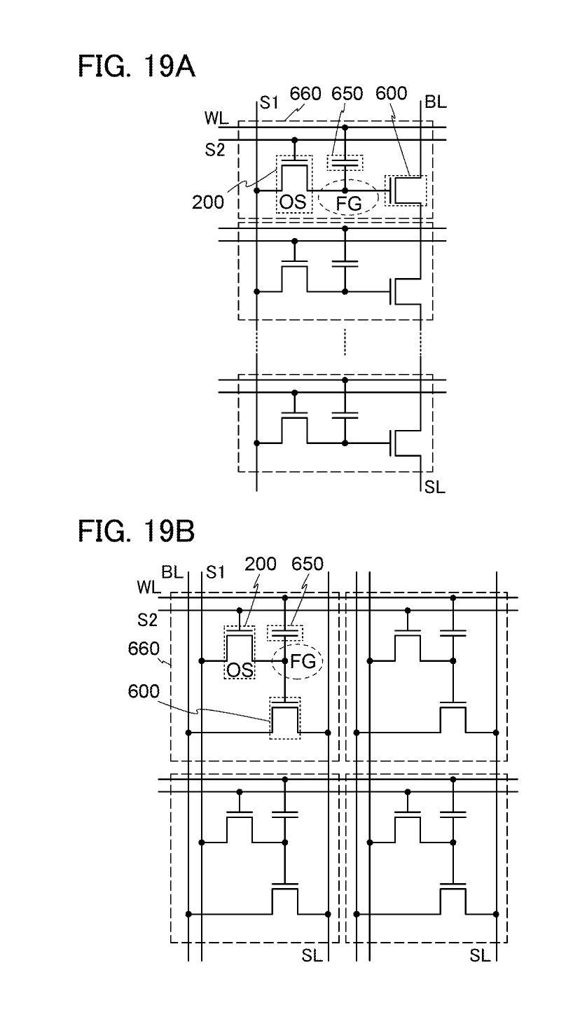

In this embodiment, application examples of the semiconductor device described in Embodiment 6 are described with reference to FIGS. 19A and 19B.

FIGS. 19A and 19B are circuit diagrams of semiconductor devices each including a plurality of memory elements (hereinafter also referred to as memory cells 660) illustrated in FIGS. 17A and 17B. FIG. 19A is a circuit diagram of a so-called NAND semiconductor device in which the memory cells 660 are connected in series, and FIG. 19B is a circuit diagram of what is called a NOR semiconductor device in which the memory cells 660 are connected in parallel.

The semiconductor device illustrated in FIG. 19A includes a source line SL, a bit line BL, a first signal line 51, a plurality of second signal lines S2, a plurality of word lines WL, and the plurality of memory cells 660. In FIG. 19A, one source line SL and one bit line BL are provided in the semiconductor device; however, one embodiment of the present invention is not limited to this structure. A plurality of source lines SL and a plurality of bit lines BL may be provided.

In each of the memory cells 660, the gate electrode of the transistor 600, one of a source electrode and a drain electrode of the transistor 200, and one electrode of the capacitor 650 are electrically connected to one another. The first signal line 51 and the other of the source electrode and the drain electrode of the transistor 200 are electrically connected to each other, and the second signal line S2 and a gate electrode of the transistor 200 are electrically connected to each other. The word line WL and the other electrode of the capacitor 650 are electrically connected to each other.

Further, the source electrode of the transistor 600 included in the memory cell 660 is electrically connected to the drain electrode of the transistor 600 in the adjacent memory cell 660. The drain electrode of the transistor 600 included in the memory cell 660 is electrically connected to the source electrode of the transistor 600 in the adjacent memory cell 660. Note that the drain electrode of the transistor 600 included in the memory cell 660 of the plurality of memory cells connected in series, which is provided at one end, is electrically connected to the bit line. In addition, the source electrode of the transistor 600 included in the memory cell 660 of the plurality of memory cells connected in series, which is provided at the other end, is electrically connected to the source line SL.

In the semiconductor device in FIG. 19A, writing operation and reading operation are performed for each row. The writing operation is performed as follows. A potential at which the transistor 200 is turned on is supplied to the second signal line S2 of a row where writing is to be performed, so that the transistor 200 of the row where writing is to be performed is turned on. Accordingly, the potential of the first signal line S1 is supplied to the gate electrode of the transistor 600 of the specified row, so that predetermined charge is given to the gate electrode. Thus, data can be written to the memory cell 660 of the specified row.

Further, the reading operation is performed as follows. First, a potential at which the transistor 600 is turned on regardless of charge given to the gate electrode of the transistor 600 is supplied to the word lines WL of rows other than a row where reading is to be performed, so that the transistors 600 of the rows other than the row where reading is to be performed are turned on. Then, a potential (reading potential) at which an on state or an off state of the transistor 600 is determined depending on charge in the gate electrode of the transistor 600 is supplied to the word line WL of the row where reading is to be performed. After that, a constant potential is supplied to the source line SL so that a reading circuit (not illustrated) connected to the bit line BL is operated. Here, the plurality of transistors 600 between the source line SL and the bit line BL are in an on state except the transistor 600 of the row where reading is to be performed; therefore, conductance between the source line SL and the bit line BL is determined by the state (an on state or an off state) of the transistor 600 of the row where reading is to be performed. The conductance of the transistor 600 of the row where reading is to be performed depends on charge in the gate electrode thereof. Thus, the potential of the bit line BL varies accordingly. By reading the potential of the bit line BL with the reading circuit, data can be read from the memory cell 660 of the specified row.

The semiconductor device illustrated in FIG. 19B includes a plurality of source lines SL, a plurality of bit lines BL, a plurality of first signal lines S1, a plurality of second signal lines S2, a plurality of word lines WL, and the plurality of memory cells 660. The gate electrode of the transistor 600, one of a source electrode and a drain electrode of the transistor 200, and one electrode of the capacitor 650 are electrically connected to one another. The source line SL and the source electrode of the transistor 600 are electrically connected to each other. The bit line BL and the drain electrode of the transistor 600 are electrically connected to each other. The first signal line S1 and the other of the source electrode and the drain electrode of the transistor 200 are electrically connected to each other, and the second signal line S2 and a gate electrode of the transistor 200 are electrically connected to each other. The word line WL and the other electrode of the capacitor 650 are electrically connected to each other.

In the semiconductor device in FIG. 19B, writing operation and reading operation are performed for each row. The writing operation is performed in a manner similar to that of the semiconductor device in FIG. 19A. The reading operation is performed as follows. First, a potential at which the transistor 600 is turned off regardless of charge given to the gate electrode of the transistor 600 is supplied to the word lines WL of rows other than a row where reading is to be performed, so that the transistors 600 of the rows other than the row where reading is to be performed are turned off. Then, a potential (reading potential) at which an on state or an off state of the transistor 600 is determined depending on charge in the gate electrode of the transistor 600 is supplied to the word line WL of the row where reading is to be performed. After that, a constant potential is supplied to the source line SL so that a reading circuit (not illustrated) connected to the bit line BL is operated. Here, conductance between the source lines SL and the bit lines BL is determined by the state (an on state or an off state) of the transistors 600 of the row where reading is to be performed. That is, the potential of the bit lines BL varies depending on charge in the gate electrodes of the transistors 600 of the row where reading is to be performed. By reading the potential of the bit line BL with the reading circuit, data can be read from the memory cell 660 of the specified row.

Although the amount of data which can be stored in each of the memory cells 660 is one bit in the above description, the structure of the memory device of this embodiment is not limited thereto. The amount of data which can be stored in each of the memory cells 660 may be increased by preparing three or more potentials to be supplied to the gate electrode of the transistor 600. For example, in the case where the number of potentials to be supplied to the gate electrode of the transistor 600 is four, data of two bits can be stored in each of the memory cells.

Note that the structures, methods, and the like described in this embodiment can be combined as appropriate with any of the structures, methods, and the like described in the other embodiments.

### Embodiment 8

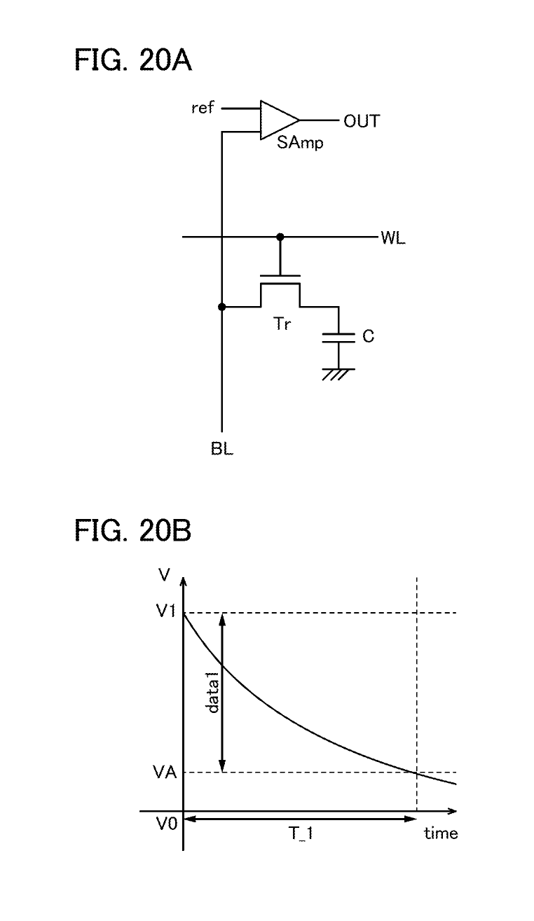

In this embodiment, a semiconductor device to which the transistor described in any of the above embodiments is applied will be described with reference to FIGS. 20A and 20B. Note that a memory element (memory cell) is described as an example of the semiconductor device also in this embodiment. The memory element has a structure different from that in the above embodiment.

FIG. 20A is a circuit diagram illustrating a memory element described in this embodiment.

The memory cell illustrated in FIG. 20A includes a bit line BL, a word line WL, a transistor Tr, and a capacitor C. A sense amplifier SAmp is electrically connected to the memory cell.

Note that it is known that the voltage held in the capacitor C is gradually decreased with time as shown in FIG. 20B owing to the off-state current of the transistor Tr. After a certain period of time, the voltage originally charged from V0 to V1 is decreased to VA which is a limit for reading data 1. This period is called a holding period T_1. In the case of a two-level memory cell, refresh needs to be performed within the holding period T_1.

The transistor described in any of the above embodiments includes an oxide semiconductor film which is highly purified and whose oxygen vacancies are filled, and thus has less change in electric characteristics and sufficiently reduced off-state current.

Therefore, when the transistor described in any of the above embodiments is used as the transistor Tr, the holding period T_1 can be extended. That is, the intervals between refresh operations can be longer. For example, in the case where the memory cell described in this embodiment is formed using a transistor whose off-state current density is reduced to several yA/μm to several zA/μm, data can be held for several days to several decades without supply of power.

Furthermore, since the transistor described in any of the above embodiments has high on-state current and high field-effect mobility, a memory cell capable of high-speed operation and high-speed response can be manufactured.

As described above, a high-performance semiconductor device can be provided by using any of the transistors described in the above embodiments.

### Embodiment 9

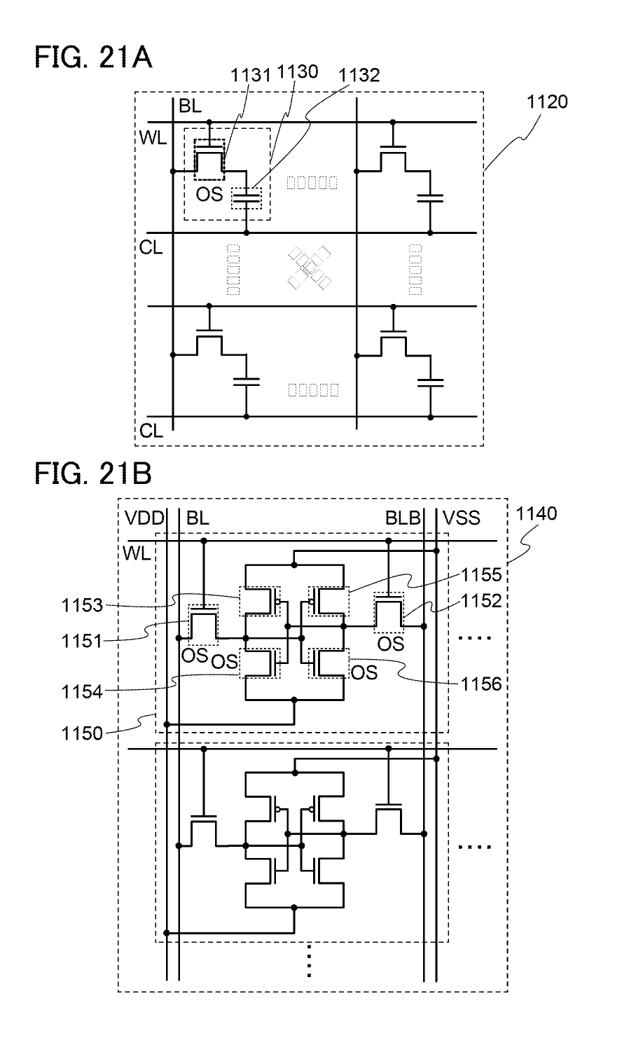

In this embodiment, a semiconductor device to which the transistor described in any of the above embodiments is applied will be described with reference to FIGS. 21A and 21B.

FIG. 21A illustrates an example of a semiconductor device whose structure corresponds to that of a so-called dynamic random access memory (DRAM). A memory cell array 1120 illustrated in FIG. 21A has a structure in which a plurality of memory cells 1130 is arranged in a matrix. Further, the memory cell array 1120 includes m first wirings and n second wirings. Note that in this embodiment, the first wiring and the second wiring are referred to as a bit line BL and a word line WL, respectively.

The memory cell 1130 includes a transistor 1131 and a capacitor 1132. A gate electrode of the transistor 1131 is electrically connected to the first wiring (the word line WL). Further, one of a source electrode and a drain electrode of the transistor 1131 is electrically connected to the second wiring (the bit line BL). The other of the source electrode and the drain electrode of the transistor 1131 is electrically connected to one electrode of the capacitor. The other electrode of the capacitor is connected to a capacitor line CL and is supplied with predetermined potential. The transistor described in any of the above embodiments is applicable to the transistor 1131.

The transistor described in any of the above embodiments includes an oxide semiconductor film which is highly purified and whose oxygen vacancies are filled, and thus has less change in electric characteristics and sufficiently reduced off-state current. With the use of such a transistor, the semiconductor device in FIG. 21A, which is regarded as a so-called DRAM, can be used as a substantially nonvolatile memory.

FIG. 21B illustrates an example of a semiconductor device whose structure corresponds to that of a so-called static random access memory (SRAM). A memory cell array 1140 illustrated in FIG. 21B can have a structure in which a plurality of memory cells 1150 is arranged in a matrix. Further, the memory cell array 1140 includes a first wiring (word line WL), a second wiring (a bit line BL), a third wiring (an inverted bit line BLB), a power supply line VDD, and a ground potential line VSS.

The memory cell 1150 includes a first transistor 1151, a second transistor 1152, a third transistor 1153, a fourth transistor 1154, a fifth transistor 1155, and a sixth transistor 1156. The first transistor 1151 and the second transistor 1152 function as selection transistors. One of the third transistor 1153 and the fourth transistor 1154 is an n-channel transistor (here, the fourth transistor 1154 is an n-channel transistor), and the other of the third transistor 1153 and the fourth transistor 1154 is a p-channel transistor (here, the third transistor 1153 is a p-channel transistor). In other words, the third transistor 1153 and the fourth transistor 1154 form a CMOS circuit. Similarly, the fifth transistor 1155 and the sixth transistor 1156 form a CMOS circuit.

The first transistor 1151, the second transistor 1152, the fourth transistor 1154, and the sixth transistor 1156 are n-channel transistors and the transistor described in any of the above embodiments is applicable to these transistors. Each of the third transistor 1153 and the fifth transistor 1155 is a p-channel transistor in which a channel formation region is formed using a material (e.g., single crystal silicon) other than an oxide semiconductor.

Since the transistor described in any of the above embodiments has high on-state current and high field-effect mobility, a semiconductor device capable of high-speed operation and high-speed response can be manufactured.

As described above, a high-performance semiconductor device can be provided by using any of the transistors described in the above embodiments.

The structures, methods, and the like described in this embodiment can be combined as appropriate with any of the other structures, methods, and the like described in the other embodiments.

### Embodiment 10

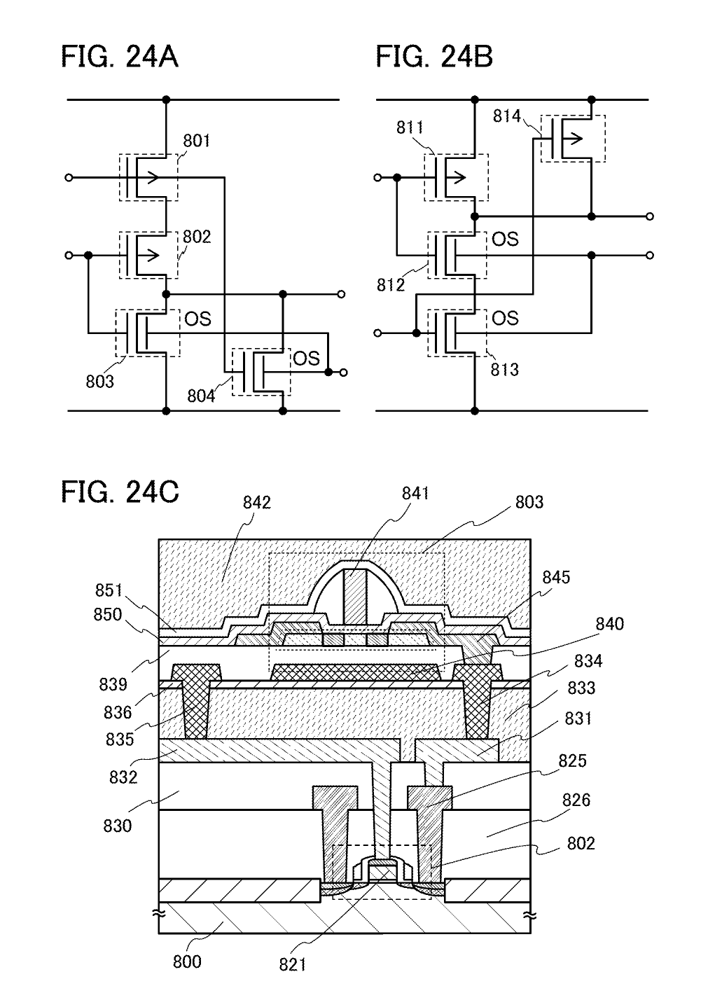

In this embodiment, a semiconductor device to which the transistor described in any of the above embodiments is applied will be described with reference to FIGS. 24A to 24C. Note that in this embodiment, a NOR circuit and a NAND circuit, which are logic circuits, are described as examples of the semiconductor device.

FIGS. 24A and 24B illustrate the logic circuits. FIG. 24A illustrates a NOR circuit and FIG. 24B illustrates a NAND circuit. FIG. 24C is a cross-sectional view illustrating a structure of a transistor 802 and a transistor 803 in the NOR circuit of FIG. 24A.

In the NOR circuit and the NAND circuit illustrated in FIGS. 24A and 24B, a transistor 801, the transistor 802, a transistor 811, and a transistor 814 are p-channel transistors. The transistor 600 (see FIG. 17A) in which a dopant (e.g., boron) providing a function as a p-channel transistor is implanted into the impurity regions 602a and 602b is applicable to the transistors 801, 802, 811, and 814.

The transistor 803, a transistor 804, a transistor 812, and a transistor 813 are n-channel transistors, and the transistor described in any of the above embodiments (e.g., the transistor 200) is applicable thereto. Note that “OS” in FIGS. 24A and 24B indicates that the transistor described in any of the above embodiments is applicable to the transistors 803, 804, 812, and 813.

Note that in the NOR circuit and the NAND circuit illustrated in FIGS. 24A an 24B, a transistor, like the one illustrated in FIG. 18, in which a conductive film is provided on a side opposite to a gate electrode with an oxide semiconductor film positioned therebetween may be applied to the transistors 803, 804, 812, and 813. By supplying a fixed potential such as a ground potential to the conductive film in such a structure, negative shift of the threshold voltage of the transistor can be suppressed; or by supplying, to the conductive film, a signal which synchronizes with a signal which is supplied to the gate electrode, on-state current of the transistor can be increased.

For example, in the NOR circuit of FIG. 24A in this embodiment, the conductive films may be provided in the transistors 803 and 804 and electrically connected to each other. Further, in the NAND circuit of FIG. 24B, the conductive films may be provided in the transistors 812 and 813 and electrically connected to each other. However, the connection relation between the conductive films is not limited those described above, the conductive films may be electrically controlled independently from each other.

Part of the NOR circuit illustrated in FIG. 24C is an example in which a single crystal silicon substrate is used as a substrate 800, the transistor 802 is formed on the single crystal silicon substrate, and the transistor 803 in which an oxide semiconductor film is used for a channel formation region is stacked over the transistor 802.

Here, a correspondence relation between the reference numerals of the transistors 802 and 803 in FIG. 24C and the reference numerals of the transistors 600 and 200 in FIG. 17A and FIG. 18 is described below. A gate electrode 821 of the transistor 802 corresponds to the gate electrode 617 and the gate electrode 603 of the transistor 600. Insulating films 826, 830, 833, and 836 each correspond to any of the insulating films 619, 623, 625, 631, and 642 in FIG. 17A or FIG. 18. Wirings 831 and 832 each correspond to any of the contact plugs and the wirings in FIG. 17A or FIG. 18. A conductive film 840 corresponds to the conductive film 680 or the conductive film 690 in FIG. 18. A base insulating film 839 corresponds to the base insulating film 103 in FIG. 17A or FIG. 18. A gate insulating film 850 corresponds to the gate insulating film 113 in FIG. 17A or FIG. 18. A gate electrode 841 corresponds to the gate electrode 117 in FIG. 17A or FIG. 18, and an insulating film 851 corresponds to the insulating film 121 in FIG. 17A or FIG. 18. An electrode 845 corresponds to the drain electrode 127b in FIG. 17A or FIG. 18. An interlayer insulating film 842 corresponds to the interlayer insulating film 123 in FIG. 17A or FIG. 18.

The gate electrode 821 of the transistor 803 is electrically connected to a wiring 835 through an opening formed in the wiring 832 and the insulating film 833. Although not illustrated, the wiring 835 is electrically connected to the gate electrode 841 via wirings provided in an opening formed in the base insulating film 839, the gate insulating film 850, the insulating film 851, and the interlayer insulating film 842 and an opening formed in the interlayer insulating film 842.

An electrode 825 (drain electrode) of the transistor 802 is electrically connected to the electrode 845 (source electrode) of the transistor 803 via the wiring 831 and a wiring 834. The wiring 831 is provided in an opening formed in the insulating film 830. The wiring 834 is provided in an opening formed in the insulating film 833 and the insulating film 836. The electrode 845 is provided in an opening formed in the base insulating film 839.

In the base insulating film 839, an oxygen excess region can be provided close to the oxide semiconductor film. Therefore, oxygen can be efficiently supplied from the oxygen excess region to the oxide semiconductor film. In addition, the supply of oxygen can be promoted by heat treatment.

Further, regarding the base insulating film 839, instead of being provided in the region in the vicinity of the interface in contact with the oxide semiconductor film that needs to be supplied with oxygen, the oxygen excess region may be provided in the vicinity of the bottom surface of the base insulating film 839, which is apart from a top surface of the base insulating film 839. Such a structure can suppress unnecessary release of oxygen from the top surface of the base insulating film 839 even when heat treatment is performed in particular, so that the base insulating film 839 can be kept in an oxygen excess state.

Accordingly, oxygen vacancies in the oxide semiconductor film and at the interface of the oxide semiconductor film can be efficiently compensated in the transistor 803. The transistors 804, 812, and 813 have the same structure as the transistor 803 and thus have the same effect as the transistor 803.

Note that the structures, methods, and the like described in this embodiment can be combined as appropriate with any of the structures, methods, and the like described in the other embodiments.

### Embodiment 11

A central processing unit (CPU) can be formed using the transistor described in any of the above embodiments for at least part of the CPU.

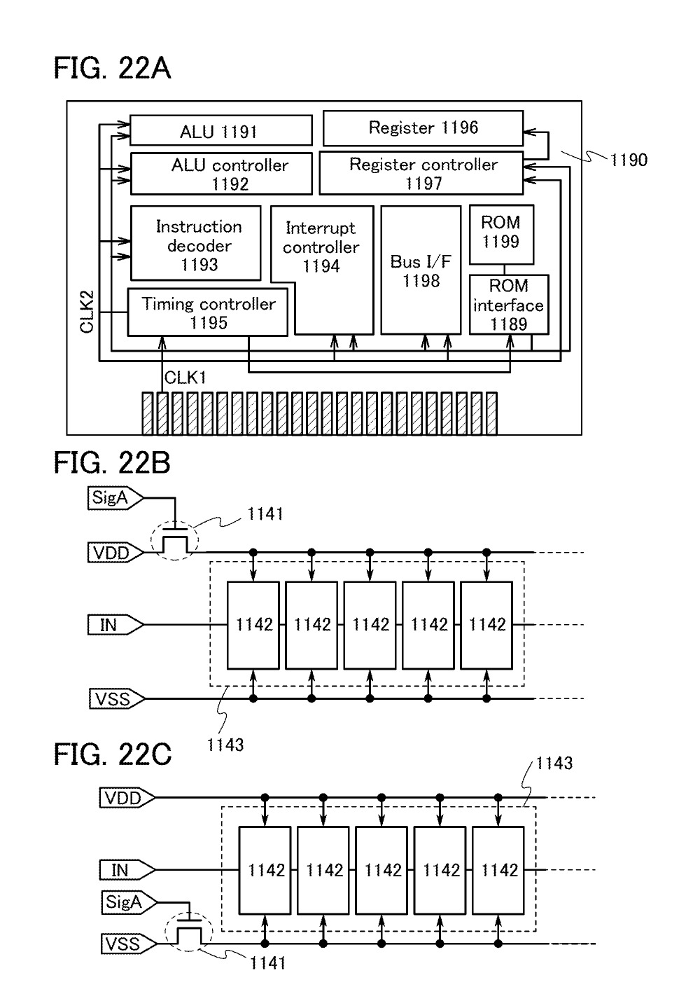

FIG. 22A is a block diagram illustrating a specific structure of a CPU. The CPU illustrated in FIG. 22A includes an arithmetic logic unit (ALU) 1191, an ALU controller 1192, an instruction decoder 1193, an interrupt controller 1194, a timing controller 1195, a register 1196, a register controller 1197, a bus interface (Bus UF) 1198, a rewritable ROM 1199, and an ROM interface (ROM UF) 1189 over a substrate 1190. A semiconductor substrate, an SOI substrate, a glass substrate, or the like is used as the substrate 1190. The ROM 1199 and the ROM interface 1189 may be provided over a separate chip. It is needless to say that the CPU in FIG. 22A is just an example of the simplified structure, and an actual CPU has various structures depending on applications.

An instruction that is input to the CPU through the Bus UF 1198 is input to the instruction decoder 1193 and decoded therein, and then input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 determines an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the clock signal CLK2 to the above circuits.

In the CPU illustrated in FIG. 22A, a memory element is provided in the register 1196. Any of the memory elements described in the above embodiments can be used as the memory element provided in the register 1196.

In the CPU illustrated in FIG. 22A, the register controller 1197 selects operation of holding data in the register 1196 in accordance with an instruction from the ALU 1191. That is, the register controller 1197 selects whether data is held by a logic element which inverts a logic (logic level) or a capacitor in the memory element included in the register 1196. When data holding by such a logic element is selected, power supply voltage is supplied to the memory element in the register 1196. When data holding by the capacitor is selected, the data is rewritten in the capacitor, and supply of power supply voltage to the memory element in the register 1196 can be stopped.

The power supply can be stopped by providing a switching element between a memory element group and a node to which a power supply potential VDD or a power supply potential VSS is supplied, as illustrated in FIG. 22B or FIG. 22C. Circuits illustrated in FIGS. 22B and 22C are described below.

FIGS. 22B and 22C each illustrate an example of a configuration of a memory circuit including a transistor in which a channel formation region is formed using an oxide semiconductor as a switching element for controlling supply of a power supply potential to a memory element.

The memory element illustrated in FIG. 22B includes a switching element 1141 and a memory element group 1143 including a plurality of memory elements 1142. Specifically, as each of the memory elements 1142, the memory element described in the above embodiment can be used. Each of the memory elements 1142 included in the memory element group 1143 is supplied with the high-level power supply potential VDD via the switching element 1141. Further, each of the memory elements 1142 included in the memory element group 1143 is supplied with a potential of a signal IN and the low-level power supply potential VSS.

In FIG. 22B, a transistor in which a channel formation region is formed using an oxide semiconductor is used as the switching element 1141, and the switching of the transistor is controlled by a signal Sig A supplied to a gate electrode thereof Note that FIG. 22B illustrates the configuration in which the switching element 1141 includes only one transistor; however, one embodiment of the present invention is not limited thereto. In the case where the switching element 1141 includes a plurality of transistors which serve as switching elements, the plurality of transistors may be connected to each other in parallel, in series, or in combination of parallel connection and series connection.

Although the switching element 1141 controls the supply of the high-level power supply potential VDD to each of the memory elements 1142 included in the memory element group 1143 in FIG. 22B, the switching element 1141 may control the supply of the low-level power supply potential VSS.

In FIG. 22C, an example of a memory device in which each of the memory elements 1142 included in the memory element group 1143 is supplied with the low-level power supply potential VSS via the switching element 1141 is illustrated. The supply of the low-level power supply potential VSS to each of the memory elements 1142 included in the memory element group 1143 can be controlled by the switching element 1141.

When a switching element is provided between a memory element group and a node to which the power supply potential VDD or the power supply potential VSS is supplied, data can be held even in the case where operation of a CPU is temporarily stopped and the supply of the power supply voltage is stopped; accordingly, power consumption can be reduced. Specifically, for example, while a user of a personal computer does not input data to an input device such as a keyboard, the operation of the CPU can be stopped, so that the power consumption can be reduced.

Although the CPU is given as an example, the transistor can also be applied to an LSI such as a digital signal processor (DSP), a custom LSI, or a field programmable gate array (FPGA).

The structures, methods, and the like described in this embodiment can be combined as appropriate with any of the other structures, methods, and the like described in the other embodiments.

### Embodiment 12

A semiconductor device disclosed in this specification can be applied to a variety of electronic appliances (including game machines). Examples of electronic appliances are a television set (also referred to as a television or a television receiver), a monitor of a computer or the like, a camera such as a digital camera or a digital video camera, a digital photo frame, a mobile phone handset (also referred to as a mobile phone or a mobile phone device), a portable game machine, a portable information terminal, an audio reproducing device, a large-sized game machine such as a pachinko machine, and the like. Examples of electronic appliances each including the semiconductor device described in the above embodiment are described.

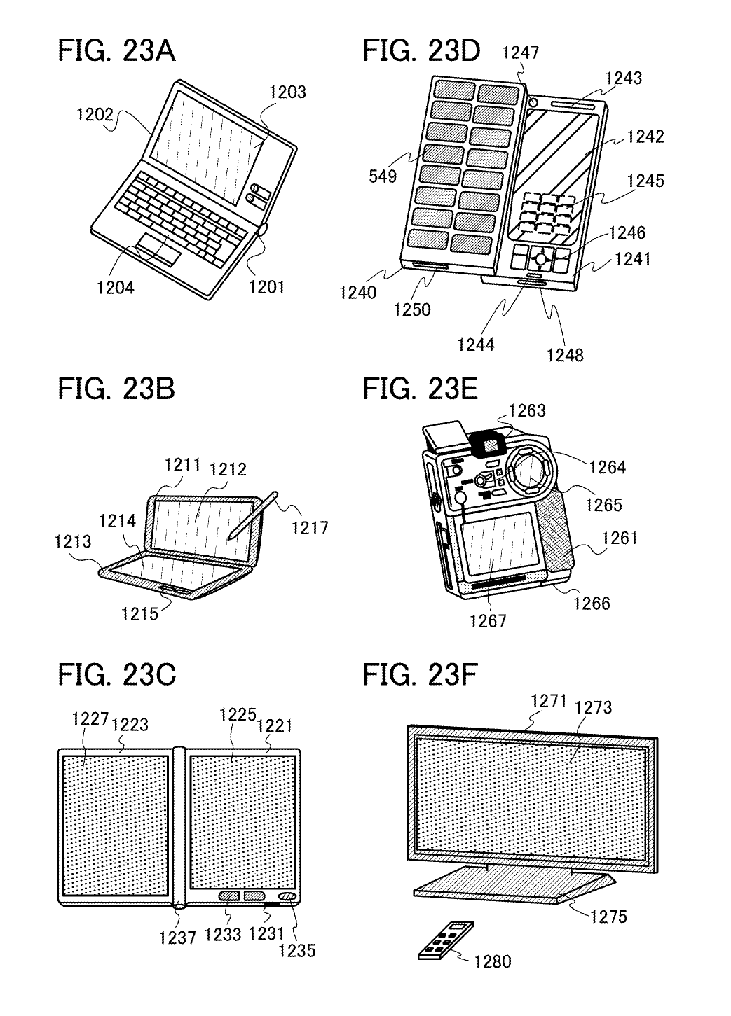

FIG. 23A is a laptop personal computer including a housing 1201, a housing 1202, a display portion 1203, a keyboard 1204, and the like. The housing 1201 and the housing 1202 each include an electronic circuit, and the electronic circuit includes the semiconductor device according to one embodiment of the present invention. Therefore, a laptop personal computer can be achieved with a high yield and high productivity. Further, since the semiconductor device according to one embodiment of the present invention has a low off-state current density and has high on-state current and high field-effect mobility, a laptop personal computer with high performance and low power consumption can be achieved.

FIG. 23B is a tablet terminal. The tablet terminal includes a housing 1211 including a display portion 1212, a housing 1213 including a display portion 1214, and operation keys 1215. In addition, a stylus 1217 for operating the tablet terminal, and the like are provided. The housing 1211 and the housing 1213 each include an electronic circuit, and the electronic circuit includes the semiconductor device according to one embodiment of the present invention. Therefore, a tablet terminal can be achieved with a high yield and high productivity. Further, since the semiconductor device according to one embodiment of the present invention has a low off-state current density and has high on-state current and high field-effect mobility, a tablet terminal with high performance and low power consumption can be achieved.

FIG. 23C is an e-book reader mounting electronic paper. The e-book reader has two housings, a housing 1221 and a housing 1223. The housing 1221 and the housing 1223 include a display portion 1225 and a display portion 1227, respectively. The housing 1221 and the housing 1223 are connected by a hinge 1237 and can be opened and closed along the hinge 1237. The housing 1221 is provided with a power supply 1231, an operation key 1233, a speaker 1235, and the like. At least one of the housing 1221 and the housing 1223 includes an electronic circuit, and the electronic circuit includes the semiconductor device according to one embodiment of the present invention. Therefore, an e-book reader can be achieved with a high yield and high productivity. Further, since the semiconductor device according to one embodiment of the present invention has a low off-state current density and has high on-state current and high field-effect mobility, an e-book reader with high performance and low power consumption can be achieved.

FIG. 23D is a mobile phone including two housings, a housing 1240 and a housing 1241. Further, the housing 1240 and the housing 1241 in a state where they are developed as illustrated in FIG. 23D can shift by sliding to a state where one is overlapped with the other; therefore, the size of the mobile phone can be reduced, which makes the mobile phone suitable for being carried. The housing 1241 includes a display panel 1242, a speaker 1243, a microphone 1244, operation keys 1245, a pointing device 1246, a camera lens 1247, an external connection terminal 1248, and the like. The housing 1240 includes a solar cell 1249 for charging the mobile phone, an external memory slot 1250, and the like. In addition, an antenna is incorporated in the housing 1241. At least one of the housing 1240 and the housing 1241 includes an electronic circuit and the electronic circuit includes the semiconductor device according to one embodiment of the present invention. Therefore, a mobile phone can be achieved with a high yield and high productivity. Further, since the semiconductor device according to one embodiment of the present invention has a low off-state current density and has high on-state current and high field-effect mobility, a mobile phone with high performance and low power consumption can be achieved.

FIG. 23E is a digital camera including a main body 1261, a display portion 1267, an eyepiece 1263, an operation switch 1264, a display portion 1265, a battery 1266, and the like. The main body 1261 includes an electronic circuit, and the electronic circuit includes the semiconductor device according to one embodiment of the present invention. Therefore, a digital camera can be achieved with a high yield and high productivity. Further, since the semiconductor device according to one embodiment of the present invention has a low off-state current density and has high on-state current and high field-effect mobility, a digital camera with high performance and low power consumption can be achieved.

FIG. 23F is a television device including a housing 1271, a display portion 1273, a stand 1275, and the like. The television device can be operated by a switch of the housing 1271 or a remote controller 1280. The housing 1271 and the remote controller 1280 each include an electronic circuit, and the electronic circuit includes the semiconductor device according to one embodiment of the present invention. Therefore, a television device can be achieved with a high yield and high productivity. Further, since the semiconductor device according to one embodiment of the present invention has a low off-state current density and has high on-state current and high field-effect mobility, a television device with high performance and low power consumption can be achieved.

The structures, methods, and the like described in this embodiment can be combined as appropriate with any of the other structures, methods, and the like described in the other embodiments.

This application is based on Japanese Patent Application serial no. 2012-091530 filed with Japan Patent Office on Apr. 13, 2012, the entire contents of which are hereby incorporated by reference.

What is claimed is:

1. A semiconductor device comprising:
a substrate;
a semiconductor film over the substrate;
a source electrode and a drain electrode in contact with the semiconductor film;
a gate electrode over the semiconductor film;
a sidewall insulating film in contact with a side surface of the gate electrode; and
a gate insulating film interposed between the semiconductor film and the gate electrode,
wherein the sidewall insulating film fills a recessed portion between the source electrode and the gate electrode.

2. A semiconductor device comprising:
a substrate;
a semiconductor film over the substrate;
a source electrode and a drain electrode in contact with the semiconductor film;
a gate electrode over the semiconductor film;
a sidewall insulating film in contact with a side surface of the gate electrode; and
a gate insulating film interposed between the semiconductor film and the gate electrode and between the source electrode and the sidewall insulating film;
wherein the sidewall insulating film fills a recessed portion between the source electrode and the gate electrode.

3. The semiconductor device according to claim 1,
further comprising an insulating film over the source electrode and the drain electrode, and on and in contact with the sidewall insulating film and a top surface of the gate electrode.

4. The semiconductor device according to claim 2,
further comprising an insulating film over the source electrode and the drain electrode, and on and in contact with the sidewall insulating film and a top surface of the gate electrode.

5. The semiconductor device according to claim 1,
wherein the sidewall insulating film overlaps a corner portion formed by a surface of the source electrode facing the gate electrode and a top surface of the source electrode.

6. The semiconductor device according to claim 2,
wherein the sidewall insulating film overlaps a corner portion formed by a surface of the gate insulating film overlapping the source electrode and facing the gate electrode and a top surface of the gate insulating film.

7. The semiconductor device according to claim 1,
wherein a side edge of the sidewall insulating film is positioned at a corner portion formed by a surface of the source electrode facing the gate electrode and a top surface of the source electrode.

8. The semiconductor device according to claim 2,
wherein a side edge of the sidewall insulating film is positioned at a corner portion formed by a surface of the gate insulating film overlapping the source electrode and facing the gate electrode and a top surface of the gate insulating film.

9. The semiconductor device according to claim 1,
wherein the semiconductor film includes a first region that overlaps with the gate electrode, a pair of second regions between which the first region is provided, and a pair of third regions between which the first region and the pair of second regions are provided, and
wherein the second regions contain a dopant.

10. The semiconductor device according to claim 2,
wherein the semiconductor film includes a first region that overlaps with the gate electrode, a pair of second regions between which the first region is provided, and a pair of third regions between which the first region and the pair of second regions are provided, and
wherein the second regions contain a dopant.

11. The semiconductor device according to claim 1,
wherein the semiconductor film includes a first region that overlaps with the gate electrode, a pair of second regions between which the first region is provided, and a pair of third regions between which the first region and the pair of second regions are provided, and
wherein the third regions contain a dopant.

12. The semiconductor device according to claim 2,
wherein the semiconductor film includes a first region that overlaps with the gate electrode, a pair of second regions between which the first region is provided, and a pair of third regions between which the first region and the pair of second regions are provided, and
wherein the third regions contain a dopant.

13. The semiconductor device according to claim 1,
wherein the semiconductor film includes a first region that overlaps with the gate electrode, a pair of second regions between which the first region is provided, and a pair of third regions between which the first region and the pair of second regions are provided,
wherein the second regions contain a first dopant and the third regions contain a second dopant, and
wherein a second dopant concentration of the third regions is higher than a first dopant concentration of the second regions.

14. The semiconductor device according to claim 2,
wherein the semiconductor film includes a first region that overlaps with the gate electrode, a pair of second regions between which the first region is provided, and a pair of third regions between which the first region and the pair of second regions are provided,
wherein the second regions contain a first dopant and the third regions contain a second dopant, and
wherein a second dopant concentration of the third regions is higher than a first dopant concentration of the second regions.

15. The semiconductor device according to claim 13,
wherein the first dopant and the second dopant are a same impurity element.

16. The semiconductor device according to claim 14,
wherein the first dopant and the second dopant are a same impurity element.

17. The semiconductor device according to claim 1,
wherein the semiconductor film comprises an oxide semiconductor.

18. The semiconductor device according to claim 2,
wherein the semiconductor film comprises an oxide semiconductor.

19. An electronic appliance including the semiconductor device according to claim 1.

20. An electronic appliance including the semiconductor device according to claim 2.
